(19) United States
(12) Patent Application Publication
(10) Pub. No.: US 2011/0058075 A1
(43) Pub. Date: Mar. 10, 2011

(54) SOLID-STATE IMAGING DEVICE AND MANUFACTURING METHOD THEREOF, AND ELECTRONIC DEVICE

(75) Inventors: Takeshi Yanagita, Tokyo (JP); Keiji Mabuchi, Kanagawa (JP)

(73) Assignee: SONY CORPORATION, Tokyo (JP)

(21) Appl. No.: 12/869,933

(22) Filed: Aug. 27, 2010

(30) Foreign Application Priority Data
Sep. 4, 2009 (JP) 2009-205188

(51) Int. Cl. H04N 5/335; H01L 31/18

(52) U.S. Cl. 348/273; 438/70; 257/E31.127

(57) ABSTRACT

A solid-state imaging device includes: photoelectric conversion units provided on an imaging face of a semiconductor substrate; a color filter provided on the imaging face; and a light shielding portion provided on the imaging face; wherein photoelectric conversion units are arrayed on the imaging face in a first direction a second direction; and wherein the color filter includes a first filter layer having high light transmissivity regarding a first wavelength band, and a second filter layer having high light transmissivity regarding a second wavelength band, with the first and second filter layers arrayed above the photoelectric conversion units arrayed in the first direction so as to extend in the first direction and be arrayed adjacently in the second direction; and wherein the light shielding portion extends in the first direction between the photoelectric conversion units arrayed in the second direction, between the first filter layer and the second filter layer.

### BACKGROUND OF THE INVENTION

1. Field of the Invention

The present invention relates to a solid-state imaging device and a manufacturing method thereof, and an electronic device.

2. Description of the Related Art

Cameras such as digital video cameras and digital still cameras include solid-state imaging apparatuses, e.g., include CMOS (Complementary Metal Oxide Semiconductor) image sensors or CCD (Charge Coupled Device) image sensors as a solid-state imaging apparatus.

With solid-state imaging devices, multiple pixels are arrayed on a face of a semiconductor substrate. Each pixel is provided with a photoelectric conversion unit. An example of the photoelectric conversion unit is a photodiode, which generates a signal charge by performing photoelectric conversion of incident light via an external optical system received at a photoreception face.

With the solid-state imaging device, an on-chip lens is disposed above the photoelectric conversion unit, for example. An arrangement has been proposed to dispose an intra-layer lens between this photoelectric conversion unit and on-chip lens. The intra-layer lens is provided to efficiently irradiate the incident light from the on-chip lens onto the photoelectric conversion unit (e.g., see Japanese Unexamined Patent Application Publication No. 2008-112944).

In the case of imaging a color image, a color filter is provided. In one arrangement, a three-primary-color filter with a Bayer array is disposed for the color filter. Other arrangements proposed include a clear bit pixel array in which a pixel array is inclined at a 45° angle and multiple green filters are arrayed so as to surround red and blue filters (e.g., see FIG. 5 of Japanese Unexamined Patent Application Publication No. 2006-211630).

A CMOS image sensor is a solid-state imaging device in which pixels are configured to include a pixel transistor besides a photoelectric conversion unit. A pixel transistor is configured of multiple transistors, so as to read out signal charge generated at the photoelectric conversion unit and output this as an electric signal to a signal line. Accordingly, an arrangement has been proposed to configure pixels so that multiple photoelectric conversion units share a pixel transistor, so as to reduce the pixel size. For example, techniques have been proposed in which two or four photoelectric conversion units share a pixel transistor (e.g., see Japanese Unexamined Patent Application Publication Nos. 2004-172950, 2006-157953, and 2006-54276).

In the event that multiple photoelectric conversion units share a pixel transistor, what is called “floating diffusion (also simply “FD”) addition” in which pixel signal addition is performed in the floating diffusion and data is output, may be performed as a driving operation. Alternatively, what is called “source follower (also simply “SF”) addition” in which pixel signal addition is performed at the vertical signal line (column line) and data is output, may be performed as a driving operation (e.g., see Japanese Unexamined Patent Application Publication No. 03-276675).

Further, for CMOS image sensors, what is called a “Backside Illumination” type in which light is received at the rear side of the semiconductor substrate, as to the front face where the pixel transistors and wiring are provided, has been proposed (e.g., see Japanese Unexamined Patent Application Publication No. 2003-31785).

### SUMMARY OF THE INVENTION

FIGS. 32 and 33 illustrate the upper face of a CMOS type image sensor 900. As shown in FIG. 32, a color filter 130J is provided on the CMOS type image sensor 900. The color filter 130J includes a red filter layer 130RJ, a green filter layer 130GJ, and a blue filter layer 130BJ, with each disposed corresponding to multiple pixels. The three primary color filter layers 130RJ, 130GJ, and 130BJ are each arrayed in a Bayer array BH, for example.

Photodiodes (not shown) are disposed below each of the filter layers 130RJ, 130GJ, and 130BJ, with incident light being transmitted through one of the filter layers 130RJ, 130GJ, and 130BJ, following which normally, the incident light is received at the photoreception face of the photodiode immediately below.

However, in the event that the incident light is input at an angle greatly inclined as to a z-direction perpendicular to the photoreception face, the incident light may not be input to the photoreception face immediately below but rather input to another photoreception face intended to receive light of another color. For example, there may be cases wherein light which has passed through the green filter layer 130GJ is input to the photoreception face immediately below an adjacent red filter layer 130RJ or blue filter layer 130BJ.

In addition, there are cases wherein incident light at near the boundary between pixels is not sufficiently bent by the optical component such as an on-chip lens or the like, and is input to the photoreception face of an adjacent pixel. In the event that pixels are formed very fine, to a pixel size of 3 μm or smaller for example, occurrence of this trouble due to diffraction of visible light rays may become conspicuous. This can lead to what is called “color mixture”, causing lower color reproducibility in the imaged color image and deterioration in image quality.

In particular, such trouble due to great inclination in the angle of the principal ray of incident light occurs more often at the perimeter portion of the imaging region. Additionally, such trouble also may occur in the event that the distance from the color filter to the photoreception face is long.

A proposal has been made to suppress occurrence of such trouble, as shown in FIG. 33, where a shielding film SM is disposed below the filter layers 130RJ, 130GJ, and 130BJ, corresponding to the boundary portions thereof. Note that the dotted lines in FIG. 33 indicate the boundary portions between the filter layers 130RJ, 130GJ, and 130BJ. However, with this arrangement, a part of the incident light is shielded by the shielding film SM and the amount of light input to the photoreception face of the photodiode decreases, leading to deterioration in sensitivity, which may result in deterioration of image quality.

It has been found desirable to provide a solid-state imaging device and a manufacturing method thereof, and an electronic device, whereby image quality of imaged images can be improved.

A solid-state imaging device according to an embodiment of the present invention includes: photoelectric conversion units provided on an imaging face of a semiconductor substrate, the photoelectric conversion units being configured to generate signal charge by receiving incident light at a photoreception face; a color filter provided on the imaging face, the color filter being configured to input the incident light and transmit the incident light to the photoreception face; and a light shielding portion provided on the imaging face, the light shielding portion being configured to shield part of the incident light transmitted through the color filter; wherein a plurality of the photoelectric conversion units are arrayed on the imaging face in a first direction and a plurality of the photoelectric conversion units are arrayed on the imaging face in a second direction orthogonal to the first direction; and wherein the color filter includes at least a first filter layer having high light transmissivity with regard to a first wavelength band, and a second filter layer having high light transmissivity with regard to a second wavelength band which is different from the first wavelength band, the first filter layer and the second filter layer each being arrayed above the photoreception faces of the plurality of photoelectric conversion units arrayed in the first direction so as to extend in the first direction and be arrayed adjacently in the second direction; and wherein the light shielding portion is formed so as to extend in the first direction at boundary portions between the plurality of photoelectric conversion units arrayed in the second direction, at boundary portions between the first filter layer and the second filter layer.

A solid-state imaging device according to an embodiment of the present invention includes: photoelectric conversion units provided on an imaging face of a semiconductor substrate, the photoelectric conversion units being configured to generate signal charge by receiving incident light at a photoreception face; a color filter provided on the imaging face, the color filter being configured to input the incident light and transmit the incident light to the photoreception face; and a light shielding portion provided on the imaging face, the light shielding portion being configured to shield part of the incident light transmitted through the color filter; wherein a plurality of the photoelectric conversion units are arrayed on the imaging face in a first direction and a plurality of the photoelectric conversion units are arrayed on the imaging face in a second direction orthogonal to the first direction; and wherein the color filter includes at least a first filter layer having high light transmissivity with regard to a first wavelength band, and a second filter layer having high light transmissivity with regard to a second wavelength band which is different from the first wavelength band, the first filter layer being arrayed above the photoreception faces of the plurality of photoelectric conversion units arrayed in the first direction so as to extend in the first direction, and including portions where the first filter layer and the second filter layer are arrayed adjacently in the second direction; and wherein the light shielding portion is formed between the plurality of photoelectric conversion units arrayed in the second direction, at boundary portions between the first filter layer and the second filter layer.

An electronic device according to an embodiment of the present invention includes: photoelectric conversion units provided on an imaging face of a semiconductor substrate, the photoelectric conversion units being configured to generate signal charge by receiving incident light at a photoreception face; a color filter provided on the imaging face, the color filter being configured to input the incident light and transmit the incident light to the photoreception face; and a light shielding portion provided on the imaging face, the light shielding portion being configured to shield part of the incident light transmitted through the color filter; wherein a plurality of the photoelectric conversion units are arrayed on the imaging face in a first direction and a plurality of the photoelectric conversion units are arrayed on the imaging face in a second direction orthogonal to the first direction; and wherein the color filter includes at least a first filter layer having high light transmissivity with regard to a first wavelength band, and a second filter layer having high light transmissivity with regard to a second wavelength band which is different from the first wavelength band, the first filter layer and the second filter layer each being arrayed above the photoreception faces of the plurality of photoelectric conversion units arrayed in the first direction so as to extend in the first direction and be arrayed adjacently in the second direction; and wherein the light shielding portion is formed so as to extend in the first direction at boundary portions between the plurality of photoelectric conversion units arrayed in the second direction, at boundary portions between the first filter layer and the second filter layer.

A method for manufacturing a solid-state imaging device according to an embodiment of the present invention includes the steps of: first formation, of photoelectric conversion units upon an imaging face of a semiconductor substrate, the photoelectric conversion units being configured to generate signal charge by receiving incident light at a photoreception face; second formation, of a color filter upon the imaging face, the color filter being configured to input the incident light and transmit the incident light to the photoreception face; and third formation, of a light shielding portion upon the imaging face, the light shielding portion being configured to shield part of the incident light transmitted through the color filter; wherein, in the first formation, a plurality of the photoelectric conversion units are arrayed on the imaging face in a first direction and a plurality of the photoelectric conversion units are arrayed on the imaging face in a second direction orthogonal to the first direction; and wherein the second formation further includes at least the steps of fourth formation, of a filter layer having high light transmissivity with regard to a first wavelength band, and fifth formation, of a second filter layer having high light transmissivity with regard to a second wavelength band which is different from the first wavelength band, the first filter layer and the second filter layer each being formed, in the fourth formation and fifth formation, so as to be arrayed above the photoreception faces of the plurality of photoelectric conversion units arrayed in the first direction so as to extend in the first direction and be arrayed adjacently in the second direction; and wherein, in the third formation, the light shielding portion is formed so as to extend in the first direction at boundary portions between the plurality of photoelectric conversion units arrayed in the second direction, at boundary portions between the first filter layer and the second filter layer.

With the above configurations, the first filter layer is provided so as to extend in the first direction upon the photoreception faces of the multiple photoelectric conversion units arrayed in the first direction, and the first filter layer and second filter layer are provided so as to be arrayed adjacently in the second direction. The light shielding portion is formed at boundary portions between the multiple photoelectric conversion units arrayed in the second direction, at boundary portions between the first filter layer and the second filter layer.

According to embodiments of the present invention, a solid-state imaging device and a manufacturing method thereof, and an electronic device, whereby image quality of imaged images can be improved, can be provided.

### BRIEF DESCRIPTION OF THE DRAWINGS

FIG. 1 is a configuration diagram illustrating the configuration of a camera according to a first embodiment of the present invention;

FIG. 2 is a block diagram illustrating the overall configuration of a solid-state imaging device according to the first embodiment;

FIG. 3 is a diagram illustrating principal portions of the circuit configuration of the solid-state imaging device according to the first embodiment;

FIG. 4 is a timing chart illustrating pulse signals to be supplied to various parts at the time of reading out signals from a pixel with the solid-state imaging device according to the first embodiment;

FIG. 5 is a diagram illustrating principal portions of the solid-state imaging device according to the first embodiment;

FIG. 6 is a diagram illustrating principal portions of the solid-state imaging device according to the first embodiment;

FIG. 7 is a diagram illustrating principal portions of the solid-state imaging device according to the first embodiment;

FIG. 8 is a diagram illustrating principal portions of the solid-state imaging device according to the first embodiment;

FIG. 9 is an enlarged cross-sectional view showing a light shielding portion according to the first embodiment;

FIG. 10 is a diagram illustrating principal portions provided with regard to steps in a method for manufacturing the solid-state imaging device according to the first embodiment;

FIG. 11 is a diagram illustrating principal portions provided with regard to steps in a method for manufacturing the solid-state imaging device according to the first embodiment;

FIG. 12 is a diagram illustrating principal portions of a solid-state imaging device according to a second embodiment of the present invention;

FIG. 13 is a diagram illustrating principal portions of the solid-state imaging device according to the second embodiment of the present invention;

FIG. 14 is a diagram illustrating principal portions of a solid-state imaging device according to a third embodiment of the present invention;

FIG. 15 is a diagram illustrating principal portions of the solid-state imaging device according to the third embodiment of the present invention;

FIG. 16 is a diagram illustrating principal portions of the solid-state imaging device according to the third embodiment of the present invention;

FIG. 17 is a diagram illustrating principal portions provided with regard to steps in a method for manufacturing the solid-state imaging device according to the third embodiment;

FIG. 18 is a diagram illustrating principal portions provided with regard to steps in a method for manufacturing the solid-state imaging device according to the third embodiment;

FIG. 19 is a diagram illustrating principal portions of a solid-state imaging device according to a fifth embodiment of the present invention;

FIGS. 20A and 20B are diagrams illustrating principal portions of the solid-state imaging device according to the fifth embodiment;

FIGS. 21A and 21B are diagrams illustrating principal portions of a solid-state imaging device according to a sixth embodiment of the present invention;

FIG. 22 is a diagram illustrating principal portions of the solid-state imaging device according to a seventh embodiment of the present invention;

FIG. 23 is a diagram illustrating principal portions of a solid-state imaging device according to the seventh embodiment;

FIG. 24 is a diagram illustrating principal portions of the solid-state imaging device according to the seventh embodiment;

FIG. 25 is a timing chart illustrating operations of the solid-state imaging device according to the seventh embodiment;

FIGS. 26A through 26C are diagrams schematically illustrating operations of the solid-state imaging device according to the seventh embodiment;

FIGS. 27A through 27C are diagrams schematically illustrating operations of the solid-state imaging device according to the seventh embodiment;

FIG. 28 is a diagram illustrating principal portions of a solid-state imaging device according to an eighth embodiment of the present invention;

FIG. 29 is a diagram illustrating principal portions of the solid-state imaging device according to the eight embodiment;

FIG. 30 is a timing chart illustrating operations of the solid-state imaging device according to the eight embodiment;

FIG. 31 is a diagram illustrating a pixel array according to a modification of an embodiment according to the present invention;

FIG. 32 is an upper plan view of a CMOS type image sensor; and

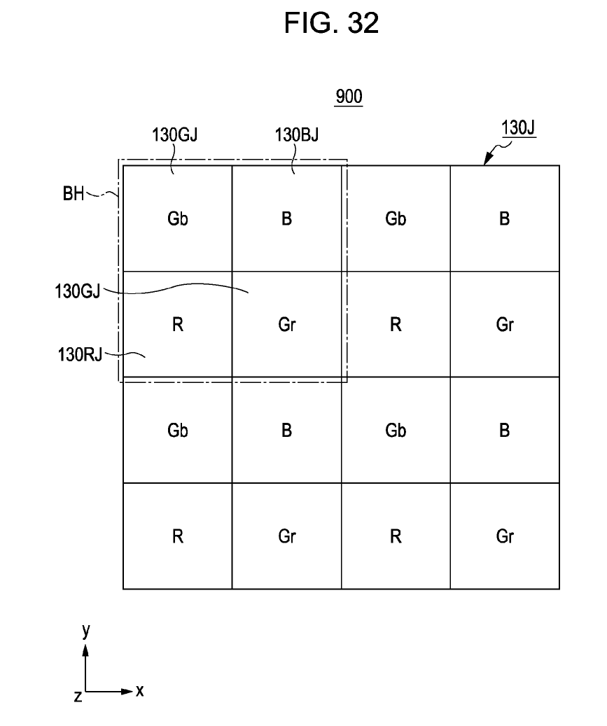

FIG. 33 is an upper plan view of a CMOS type image sensor.

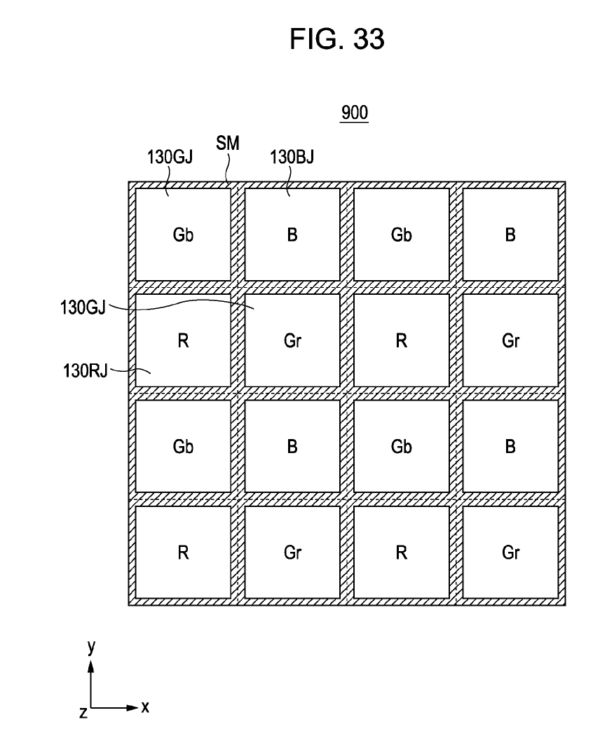

### DESCRIPTION OF THE PREFERRED EMBODIMENTS

Embodiments of the present invention will be described with reference to the drawings. Note that description will proceed in the following order.
1. First Embodiment (Case where filters of each color and light shielding portion are in the form of stripes (long in the vertical direction))
2. Second Embodiment (Case where filters of each color and light shielding portion are in the form of stripes (long in the horizontal direction))
3. Third Embodiment (Case where filters of each color are in the form of stripes (long in the horizontal direction) and the light shielding portion is in a grid form)
4. Fourth Embodiment (Case where filters of each color are in the form of stripes (long in the vertical direction) and the light shielding portion is in a grid form)
5. Fifth Embodiment (Case where the light shielding portion differs according to the position on the imaging face)
6. Sixth Embodiment (Case where the layered faces of the filter layers of each floor differ according to the position on the imaging face)
7. Seventh Embodiment (Case of performing FD addition in the vertical direction)
8. Eighth Embodiment (Case of performing SF addition in the vertical direction)
9. Others

### 1. First Embodiment

### A. Configuration of Apparatus

### A-1. Primary Configuration of Camera

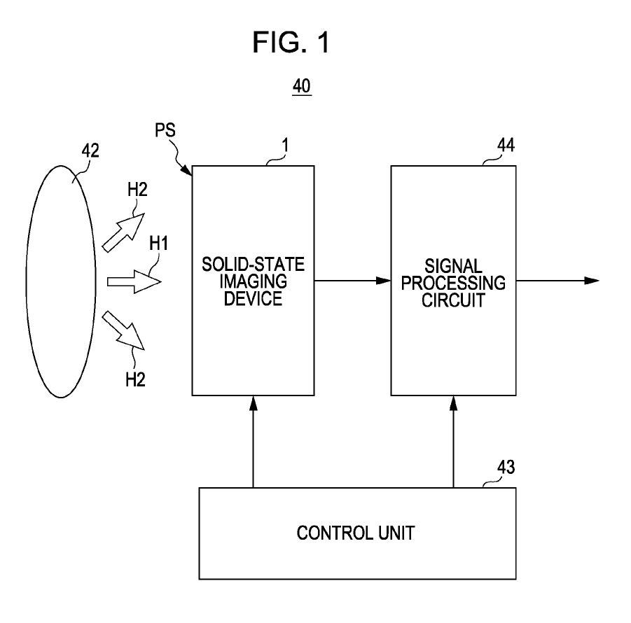

FIG. 1 is a configuration diagram illustrating the configuration of a camera 40 according to a first embodiment of the present invention. As shown in FIG. 1, the camera 40 includes a solid-state imaging device 1, an optical system 42, a control unit 43, and a signal processing unit 44. These components will be described in order.

The solid-state imaging device 1 generates signal charges by receiving incident light (a subject image) from a subject plane PS via the optical system 42 and performing photoelectric conversion thereof. Here, the solid-state imaging device 1 is driven based on control signals output from the control unit 43, and more specifically, reads out signal charges and outputs these as raw data.

As shown in FIG. 1, with the present embodiment, at the center portion of the subject plane PS of the solid-state imaging device 1, a principal ray H1 emitted from the optical system 42 is input to the subject plane PS at an angle perpendicular thereto. On the other hand, at the perimeter of the subject plane PS, principal rays H2 are input to the subject plane PS of the solid-state imaging device 1 at an angle inclined as to the perpendicular direction.

The optical system 42 is configured including optical members such as an imaging lens, diaphragm, and so forth, and is disposed such that light H from an input subject image is collected at the subject plane PS of the solid-state imaging device 1. With the present embodiment, the optical system 42 is provided so as to correspond to the center of the subject plane PS of the solid-state imaging device 1. Accordingly, as shown in FIG. 1, the optical system 42 emits the principal ray H1 to the center portion of the subject plane PS of the solid-state imaging device 1 at an angle perpendicular to the subject plane PS. On the other hand, the optical system 42 emits the principal rays H2 to the perimeter portions of the subject plane PS of the solid-state imaging device 1 at an angle inclined as to the subject plane PS. This is due to the distance of the exit pupil from the sensor plane, formed by the diaphragm, being finite.

The control unit 43 outputs various types of control signals to the solid-state imaging device 1 and the signal processing circuit 44, to control and drive the solid-state imaging device 1 and the signal processing circuit 44. The signal processing circuit 44 executes signal processing regarding the raw data output from the solid-state imaging device 1, thereby generating a digital image regarding the subject image.

### A-2. Principal Configuration of Solid-State Imaging Device

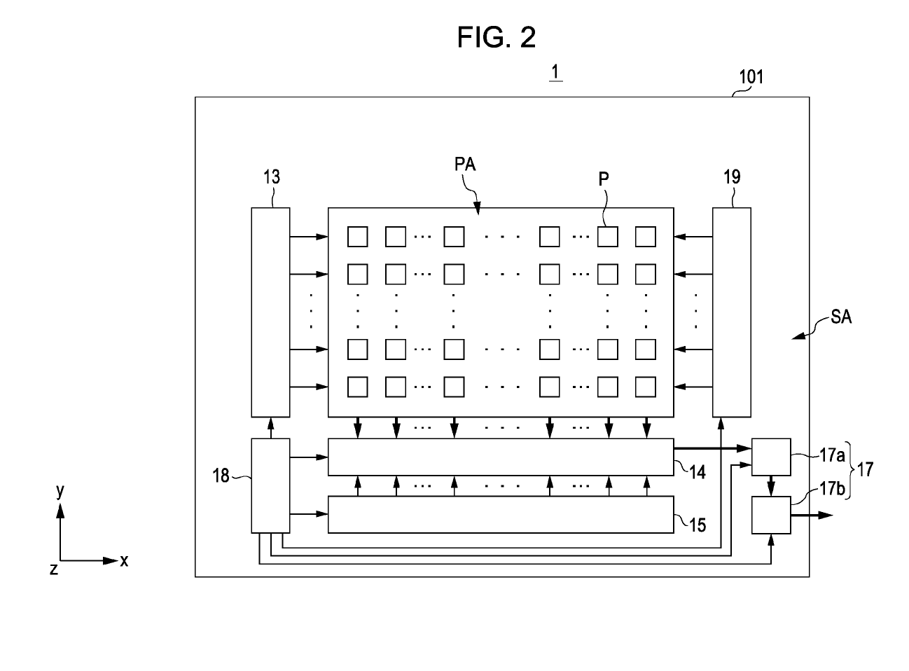

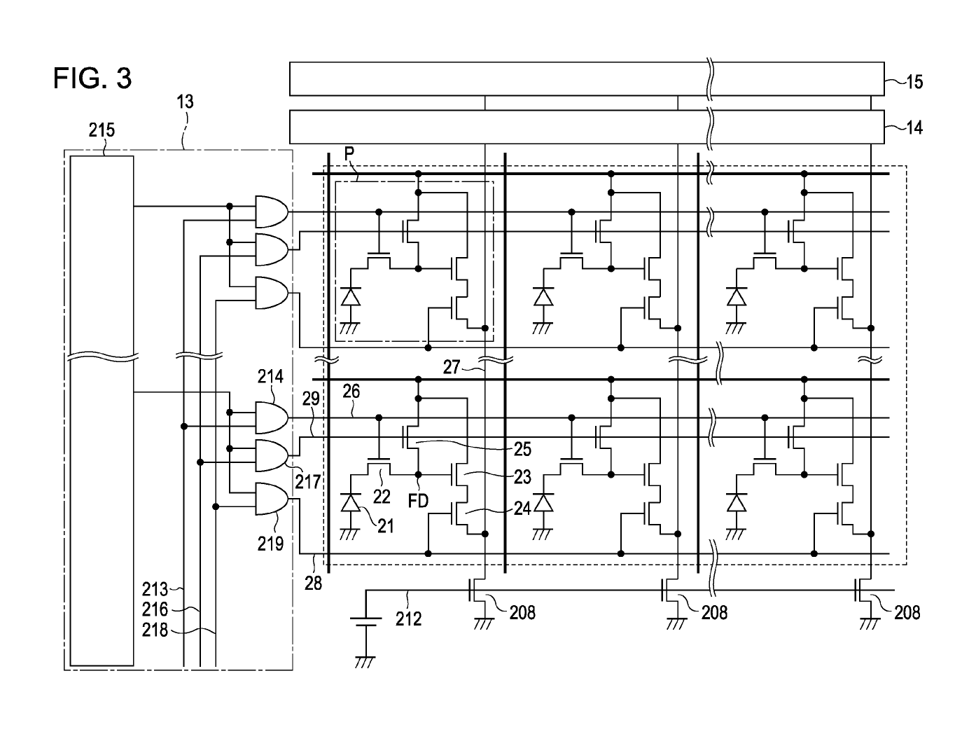

The overall configuration of the solid-state imaging device 1 will now be described. FIG. 2 is a block diagram illustrating the overall configuration of the solid-state imaging device 1 according to the first embodiment of the present invention, and FIG. 3 is a diagram illustrating principal portions of the circuit configuration of the solid-state imaging device 1 according to the first embodiment.

The solid-state imaging device 1 according to the present embodiment is a CMOS type image sensor, and as shown in FIG. 2, includes a substrate 101. The substrate 101 is a semiconductor substrate formed of silicon for example, and as shown in FIG. 2 includes an imaging region PA and a periphery region SA on the face of the substrate 101.

As shown in FIG. 2, the imaging region PA has a rectangular shape, with multiple pixels P being arrayed on both the horizontal direction x and vertical direction y. That is to say, the pixels P are arrayed in matrix fashion. At the imaging region PA, the centers thereof are arrayed corresponding to the optical axis of the optical system 42 shown in FIG. 1. This imaging region PA corresponds to the subject plane PS shown in FIG. 1. Accordingly, the principal ray (H1 in FIG. 1) is input to the pixels P arrayed at the center portion of the imaging region PA at an angle perpendicular to the face of the imaging region PA. On the other hand, the principal rays (H2 in FIG. 1) are input to the pixels P arrayed at the perimeter portions of the imaging region PA at an angle inclined as to the face of the imaging region PA.

The pixels P provided to the imaging region PA include, as shown in FIG. 3, a photodiode 21, a transfer transistor 22, an amplifier transistor 23, a selecting transistor 24, and a reset transistor 25. That is to say, each pixel P is provided so as to include a photodiode 21 and pixel transistors for performing readout of signal charges from the photodiode 21.

A pixel P receives light from a subject image at the photodiode 21, and generates signal charges by performing photoelectric conversion of the received light, which is accumulated. As shown in FIG. 3, the photodiode 21 is connected to the gated of the amplifier transistor 23 via the transfer transistor 22. With the photodiode 21, the accumulated signal charge is transferred, by the transfer transistor 22, to the floating diffusion FD connected to the gate of the amplifier transistor 23, as output signals.

At a pixel P, the transfer transistor 22 is configured so as to output signal charges generated at the photodiode 21 to the gate of the amplifier transistor 23 as electric signals. Specifically, as shown in FIG. 3, the transfer transistor 22 is provided between the photodiode 21 and the floating diffusion FD. Upon being provided with a transfer signal from a transfer line 26 to the gate thereof, the transfer transistor 22 transfers the signal charge accumulated at the photodiode 21 to the floating diffusion FD as an output signal.

At a pixel P, the amplifier transistor 23 is configured so as to amplify and output the electric signals output from the transfer transistor 22. Specifically, as shown in FIG. 3, the amplifier transistor 23 has the gate thereof connected to the floating diffusion FD. Also, the amplifier transistor 23 has the drain thereof connected to a power source potential supply line Vdd, and the source thereof connected to the selecting transistor 24. Upon the selecting transistor 24 going to an on state, the amplifier transistor 23 is supplied with a constant current from a constant current source (not shown) provided outside of the imaging region PA, and acts as a source follower. Accordingly, upon a selection signal being supplied to the selecting transistor 24, the amplifier transistor 23 amplifies output signals output from the floating diffusion FD.

At a pixel P, the selecting transistor 24 is configured so as to output an electric signal output by the amplifier transistor 23 to a vertical signal line 27 upon a selection signal being input. Specifically, as shown in FIG. 3, the selecting transistor 24 has the gate thereof connected to an address line 28 over which selection signals are supplied. Upon a selection signal being supplied, the selecting transistor 24 goes on, and outputs output signals amplified by the amplifier transistor 23 as described above to the vertical signal line 27.

At a pixel P, the reset transistor 25 is configured so as to reset the gate potential of the amplifier transistor 23. Specifically, as shown in FIG. 3, the reset transistor 25 has the gate thereof connected to a reset line 29 over which are supplied reset signals. Also, the reset transistor 25 has the drain thereof connected to the power source potential supply line Vdd, and the source thereof connected to the floating diffusion FD. Upon a reset signal being supplied to the gate from the reset line 29, the reset transistor 25 resets the gate potential of the amplifier transistor 23 to the power source potential via the floating diffusion FD.

The periphery region SA is situated around the imaging region PA, as shown in FIG. 2. Peripheral circuits are provided to the periphery region SA. Specifically, as shown in FIG. 2, a vertical driving circuit 13, a column circuit 14, a horizontal driving circuit 15, an external output circuit 17, a timing generator (TG) 18, and a shutter driving circuit 19, are provided as peripheral circuits.

As shown in FIG. 2, the vertical driving circuit 13 is provided to the side of the imaging region PA in the periphery region SA, and is configured so as to select and drive the pixels P of the imaging region PA in increments of rows. Specifically, as shown in FIG. 3, the vertical driving circuit 13 includes a vertical selecting unit 215, with a plurality of a first row selecting AND terminal 214, a second row selecting AND terminal 217, and a third row selecting AND terminal 219 being provided, so as to correspond to rows of pixels P.

In the vertical driving circuit 13, the vertical selecting unit 215 includes a shift register for example, electrically connected to the first row selecting AND terminal 214, second row selecting AND terminal 217, and third row selecting AND terminal 219. The vertical selecting unit 215 outputs control signals to the first row selecting AND terminal 214, second row selecting AND terminal 217, and third row selecting AND terminal 219, so as to sequentially select and drive the rows of the pixels P.

With the vertical driving circuit 13, one input end of the first row selecting AND terminal 214 is connected to the vertical selecting unit 215, as shown in FIG. 3. The other input end is connected to a pulse terminal 213 which supplies transfer signals. The output terminal is connected to the transfer line 26.

With the vertical driving circuit 13, one input end of the second row selecting AND terminal 217 is connected to the vertical selecting unit 215, as shown in FIG. 3. The other input end is connected to a pulse terminal 216 which supplies reset signals. The output terminal is connected to the reset line 29.

With the vertical driving circuit 13, one input end of the third row selecting AND terminal 219 is connected to the vertical selecting unit 215, as shown in FIG. 3. The other input end is connected to a pulse terminal 218 which supplies selection signals. The output terminal is connected to the address line 28.

As shown in FIG. 2, the column circuit 14 is provided at the lower end of the imaging region PA in the periphery region SA, and performs signal processing regarding signals output from the pixels P in increments of columns. The column circuit 14 is electrically connected to the vertical signal line 27 as shown in FIG. 3, and performs signal processing regarding signals output via the vertical signal line 27. Here, the column circuit 14 includes an unshown CDS (Correlated Double Sampling) circuit, and performs signal processing in which fixed pattern noise is removed.

The horizontal driving circuit 15 is electrically connected to the column circuit 14, as shown in FIG. 2. The horizontal driving circuit 15 includes a shift register for example, and sequentially outputs signals held at the column circuit 14 in increments of columns, to the external output circuit 17.

As shown in FIG. 2, the external output circuit 17 is electrically connected to the column circuit 14, and performs signal processing regarding signals output from the column circuit 14, which are then externally output. The external output circuit 17 includes an AGC (Automatic Gain Control) circuit 17a and an ADC (Analog-to-Digital Circuit) 17b. At the external output circuit 17, the AGC circuit 17a applies gain to the signals, following which the ADC 17b converts the signals from analog signals to digital signals, which are then externally output.

The timing generator 18 is electrically connected to the vertical driving circuit 13, column circuit 14, horizontal driving circuit 15, external output circuit 17, and shutter driving circuit 19, as shown in FIG. 2. The timing generator 18 generates various types of timing signals, and outputs these to the vertical driving circuit 13, column circuit 14, horizontal driving circuit 15, external output circuit 17, and shutter driving circuit 19, thereby performing driving control of each.

The shutter driving circuit 19 is configured so as to select pixels in increments of rows, and adjust the exposure time at the pixels P.

Besides the above, in the periphery region SA, multiple transistors 208 are formed corresponding to each of the multiple vertical signal lines 27, to supply constant current to the vertical signal lines 27. The transistors 208 have their gates connected to a constant potential supply line 212. With a constant potential being applied to the gates thereof by the constant potential supply line 212 so as to supply a constant current. The transistors 208 supply constant current to the amplifier transistors 23 of selected pixels, so as to function as source followers. Accordingly, a potential having a certain voltage difference as to the potential of the amplifier transistor 23 is manifested on the vertical signal line 27.

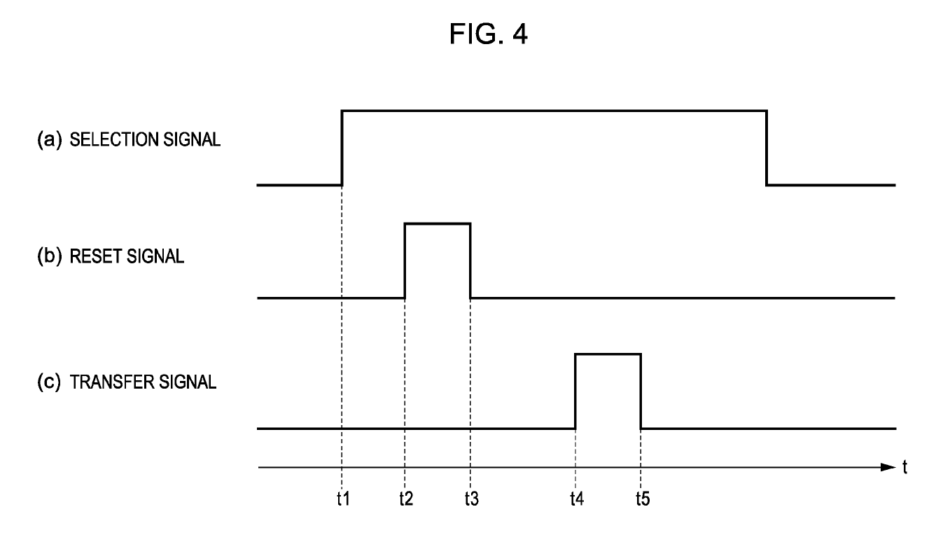

FIG. 4 is a timing chart illustrating pulse signals to be supplied to various parts at the time of reading out signals from pixels with the first embodiment. In FIG. 4, (a) represents a selection signal, (b) represents a reset signal, and (c) represents a transfer signal.

First, as shown in FIG. 4, at a first point-in-time t1, the selection signal goes to a high level, so the selecting transistor 24 is in a conducting state. At a second point-in-time t2, the reset signal goes to a high level, so the reset transistor 25 is in a conducting state. Thus, the gate potential of the amplifier transistor 23 is reset.

Next, at a third point-in-time t3, the reset signal goes to a low level, so the reset transistor 25 is in a non-conducting state. Subsequently, voltage corresponding to the reset level is read out to the column circuit 14.

Next, at a fourth point-in-time t4, the transfer signal goes to a high level, so the transfer transistor 22 is in a conducting state, and the signal charge stored in the photodiode 21 is transferred to the gate of the amplifier transistor 23.

Next, at a point-in-time t5, the transfer signal goes to a low level, so the transfer transistor 22 is in a non-conducting state. Subsequently, a voltage of a signal level corresponding to the amount of accumulated signal charge is read out to the column circuit 14 as a pixel signal.

The column circuit 14 performs difference processing regarding the reset level read out first, and the signal level read out later. Accordingly, fixed pattern noise generated due to irregularities in the threshold voltage Vth of the transistors provided at each pixel P is cancelled out from the pixel signals.

Operations for driving the pixels as described above are performed simultaneously for the multiple pixels arrayed in increments of rows, since the gates of the transistors 22, 24, and 25 are connected in increments of rows made up of multiple pixels arrayed in the horizontal direction x. Specifically, piles are sequentially selected in the vertical direction in increments of horizontal lines (pixel rows), by selection signals supplied from the above-described vertical driving circuit 13. The transistors of each of the pixels are controlled by various types of timing signals output from the timing generator 18. Accordingly, the output signals from the pixels are read out to the column circuit 14 via the vertical signal line 27. The signals accumulated at the column circuit 14 are selected by the horizontal driving circuit 15, and sequentially output to the external output circuit 17.

### A-3. Detailed Configuration of Solid-State Imaging Device

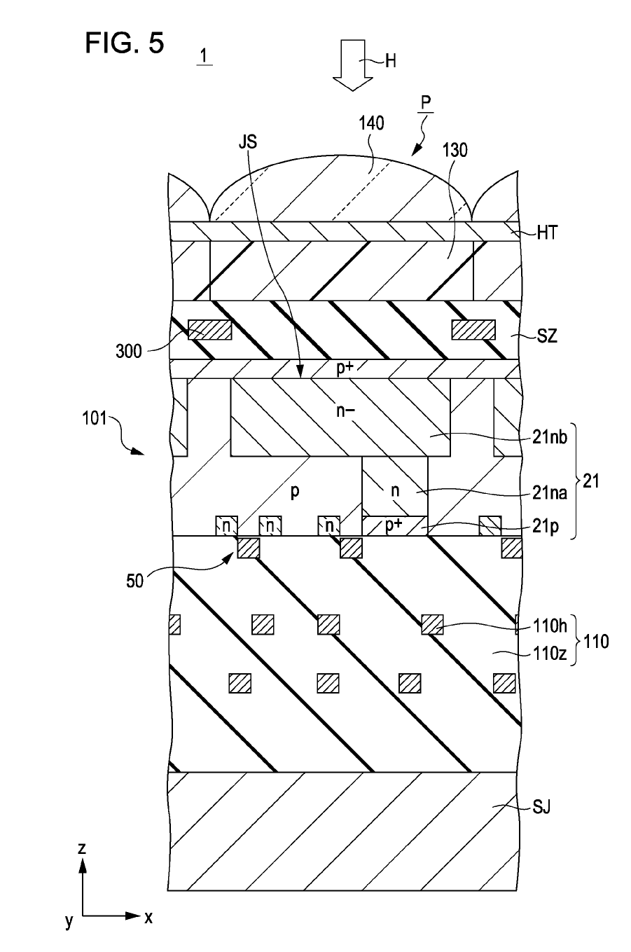

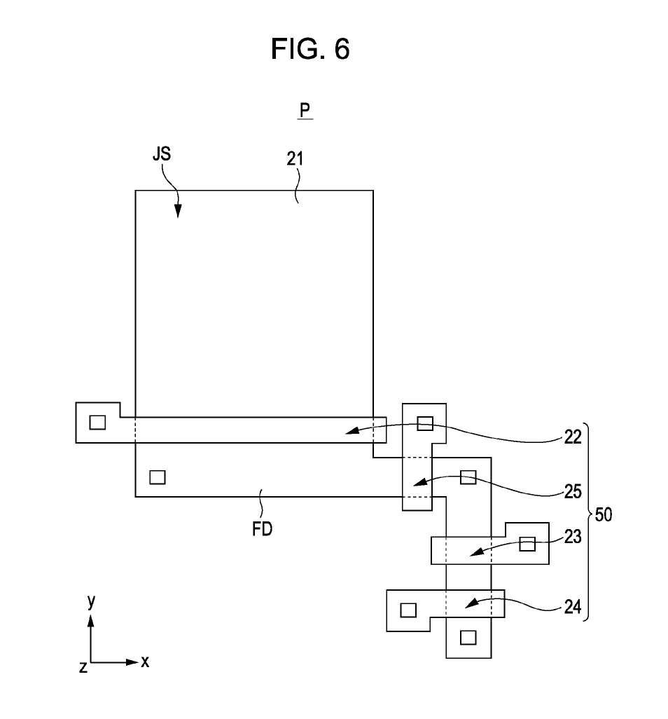

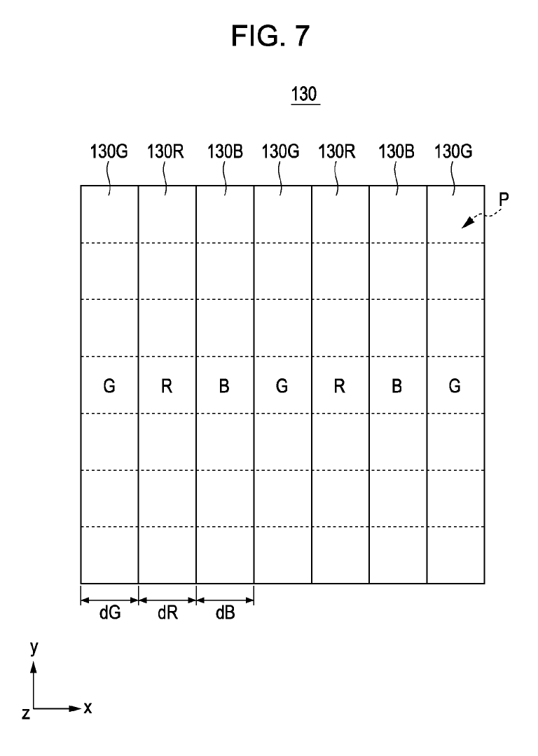

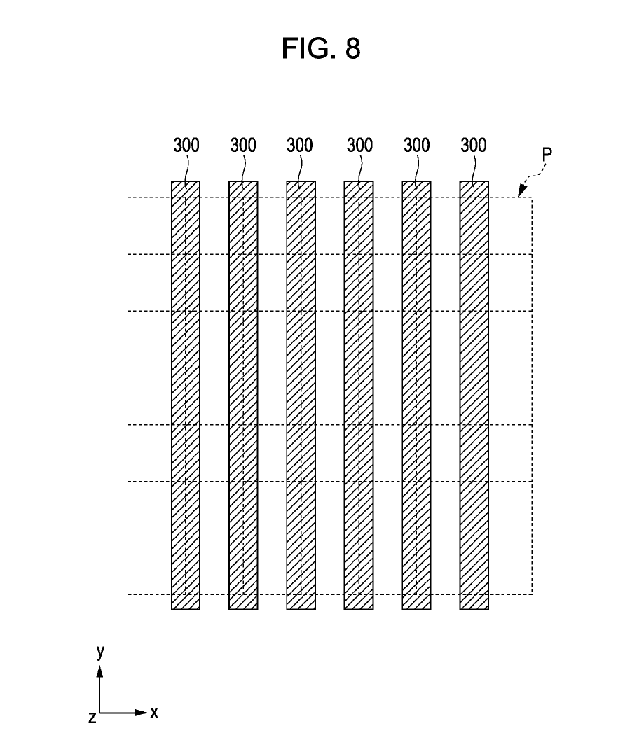

The solid-state imaging device 1 according to the present embodiment will be described in detail. FIGS. 5 through 8 are diagrams illustrating principal portions of the solid-state imaging device 1 according to the first embodiment. FIG. 5 schematically illustrates the cross-section of a pixel P provided in the imaging region PA, FIG. 6 schematically illustrates the upper face of a pixel P provided in the imaging region PA, FIG. 7 illustrates the upper face of a color filter 130, and FIG. 8 illustrates the upper face of a light shielding portion 300.

As shown in FIG. 5, the solid-state imaging device 1 is what is called a “Backside Illumination” type, in which light H input from the rear side of a semiconductor substrate 101 is received via various parts and imaging is performed. The solid-state imaging device 1 includes the substrate 101. The substrate 101 of the solid-state imaging device 1 is a silicon semiconductor substrate, and is provided with the photodiode 21, a pixel transistor 50, a color filter 130, an on-chip lens 140, and a light shielding portion 300. The substrate 101 is polished by CMP (Chemical Mechanical Polishing) for example, to a thickness of 1 to 20 μm.

As shown in FIG. 5, with the solid-state imaging device 1, a photodiode 21 is formed within the substrate 101. Also, a pixel transistor 50 is formed on the front side (lower side in FIG. 5) of the substrate 101. The color filter 130 and on-chip lens 140 and light shielding portion 300 are formed on the side of the substrate 101 opposite to the side on which the pixel transistor 50 is formed, i.e., on the upper side in FIG. 5. Each part will be described in detail next.

### A-3-1. About the Photodiode

With the solid-state imaging device 1, the photodiode 21 is provided within the substrate 101, as shown in FIGS. 5 and 6. Multiple photodiodes 21 are disposed on the face of the substrate 101 so as to correspond to each of the multiple pixels P shown in FIG. 2. That is to say, the multiple photodiodes 21 are arrayed so as to be at equal intervals in the horizontal direction x and the vertical direction y which is perpendicular to the horizontal direction x, on the imaging face (x-y face).

The photodiodes 21 are configured to generate signal charges by receiving incident light at a photoreception face JS and performing photoelectric conversion thereof. Specifically, a photodiode 21 includes a p+ region 21p, n region 21na, and +region 21nb, with the regions 21b, 21na, and 21nb being sequentially provided within a p-well of the substrate 101, in order from the rear side toward the front side.

As shown in FIG. 6, each photodiode 21 has a transfer transistor 22 provided adjacent thereto, so that the accumulated signal charge is transferred to the floating diffusion FD by the transfer transistor 22.

### A-3-2. About the Pixel Transistor

With the solid-state imaging device 1, the pixel transistor 50 is provided to the front side (lower side in FIG. 5) of the substrate 101, as shown in FIGS. 5 and 6. The pixel transistor 50 has an activated region formed on the substrate 101, with a gate electrode formed using polysilicon, for example. As shown in FIG. 6, the pixel transistor 50 includes the transfer transistor 22, amplifier transistor 23, selecting transistor 24, and reset transistor 25. The transfer transistor 22, amplifier transistor 23, selecting transistor 24, and reset transistor 25 make up part of the circuit shown in FIG. 3, being driven so as to read out the signal charge from the photodiode 21 and output to the vertical signal line 27 as a pixel signal.

On the rear side of the substrate 101 from which the pixel transistor 50 is formed, a wiring portion 110 is formed as shown in FIG. 5. The wiring portion 110 includes an insulating layer 110z and wiring 110h as shown in FIG. 5. In the wiring portion 110, the insulating layer 110z is formed so as to cover the rear face of the substrate 101. The insulating layer 110z is formed of a light transmitting material. For example, the insulating layer 110z may be formed of a silicon dioxide film. A plurality of the wiring 110h is formed of a metal material such as aluminum, within the insulating layer 110z. Each wiring 110h is connected to a respective device, so as to function as wiring for the transfer line 26, address line 28, vertical signal line 27, reset line 29, and so forth. As shown in FIG. 5, a supporting plate SJ is adhered by an adhesive layer on the surface of the wiring portion 110.

### A-3-3. About the Color Filter

With the solid-state imaging device 1, the color filter 130 is provided on the side of the substrate 101 opposite to the face on which the wiring portion 110 has been formed, as shown in FIG. 5. Here, the color filter 130 is formed on an inter-layer insulating film SZ. The color filter 130 is configured so that incident light of the subject image is input, and transmits to the photoreception face JS of the photodiode 21. The color filter 130 is formed by, for example, application of a coating liquid including a colorant pigment and photoresist resin by a coating method such as spin coating to form a coated film, following which the coated film is patterned by a lithography technique.

As shown in FIG. 7, the color filter 130 includes a red filter layer 130R, a green filter layer 130G, and a blue filter layer 130B. A plurality of each of the red filter layer 130R, green filter layer 130G, and blue filter layer 130B, are provided corresponding to each pixel P, so as to serve as the color filter 130.

With the present embodiment, the red filter layer 130R, green filter layer 130G, and blue filter layer 130B, are each arrayed in stripes according to color, as shown in FIG. 7. Here, the red filter layer 130R, green filter layer 130G, and blue filter layer 130B are arrayed extending in the vertical direction y. Each of the red filter layer 130R, green filter layer 130G, and blue filter layer 130B, are formed such that the respective widths dG, dR, and dB defined in the horizontal direction x, are the same, that is to say, dG=dR=dB.

Specifically, with the color filter 130, the red filter layer 130R is formed to extend in the vertical direction y on the imaging face (x-y face) as shown in FIG. 7. Here, the red filter layer 130R is formed so as to cover multiple pixels P arrayed in the vertical direction y. The red filter layer 130R is also positioned so as to be sandwiched between the green filter layer 130G on one side and the blue filter layer 130B on the other side. The red filter layer 130R is configured such that transmissivity is high at a wavelength band corresponding to the color red (e.g., 625 to 740 nm).

Also, with the color filter 130, the green filter layer 130G is formed to extend in the vertical direction y on the imaging face (x-y face) as shown in FIG. 7. Here, the green filter layer 130G is formed so as to cover multiple pixels P arrayed in the vertical direction y, in the same way as with the red filter layer 130R. The green filter layer 130G is also positioned so as to be sandwiched between the red filter layer 130R on one side and the blue filter layer 130B on the other side. The green filter layer 130G is configured such that transmissivity is high at a wavelength band corresponding to the color green (e.g., 500 to 565 nm).

Further, with the color filter 130, the blue filter layer 130B is formed to extend in the vertical direction y on the imaging face (x-y face) as shown in FIG. 7. Here, the blue filter layer 130B is formed so as to cover multiple pixels P arrayed in the vertical direction y, in the same way as with the red filter layer 130R and green filter layer 130G. The blue filter layer 130B is also positioned so as to be sandwiched between the red filter layer 130R on one side and the green filter layer 130G on the other side. The blue filter layer 130B is configured such that transmissivity is high at a wavelength band corresponding to the color blue (e.g., 450 to 485 nm).

The width of the filter layers 130R, 130G, and 130B extending in the vertical direction y is formed to be, for example, 0.5 to 5 μm.

### A-3-4. About the On-Chip Lens

With the solid-state imaging device 1, the on-chip lens 140 is provided on the rear face side of the substrate 101, as shown in FIG. 5. The on-chip lens 140 here is provided on the upper face of a smoothed film HT formed of a transmissive material which is formed on the upper face of the color filter 130. Multiple on-chip lenses 140 are provided, so as to correspond to each of the multiple pixels P.

The on-chip lens 140 is configured so as to collect incident light to the photoreception face JS of the photodiode 21 of each pixel P. Specifically, the on-chip lens 140 is formed such that the center is thicker than the rim, in the direction toward the photoreception face JS of the photodiode 21.

### A-3-5. About the Light Shielding Portion

With the solid-state imaging device 1, the light shielding portion 300 is provided on the rear face side of the substrate 101, as shown in FIG. 5. The light shielding portion 300 is configured so as to shield light H input to the rear face of the substrate 101, between the multiple pixels P. Examples of the material of which the light shielding portion 300 is formed include aluminum and tungsten.

Specifically, the light shielding portion 300 is formed in stripes as shown in FIG. 8. The light shielding portion 300 extends in the vertical direction y at boundary portions between the multiple pixels P arrayed in the horizontal direction x, with multiple light shielding portions 300 arrayed at equal intervals in the horizontal direction x. On the other hand, no light shielding portion 300 is provided at the boundary portions between the multiple pixels P arrayed in the vertical direction y.

That is to say, a plurality of the light shielding portion 300 are arrayed in a direction perpendicular to the longitudinal direction in which the filter layers 130R, 130G, and 130B extend, i.e., in the y direction in which the filter layers 130R, 130G, and 130B are arrayed. With the light shielding portion 300, the width of the portions extending in the vertical direction y is formed so as to be, of example, 0.1 to 1 μm, for example. As shown in FIG. 5, the light shielding portion 300 is formed within the inter-layer insulating film SZ covering the rear face of the substrate 101.

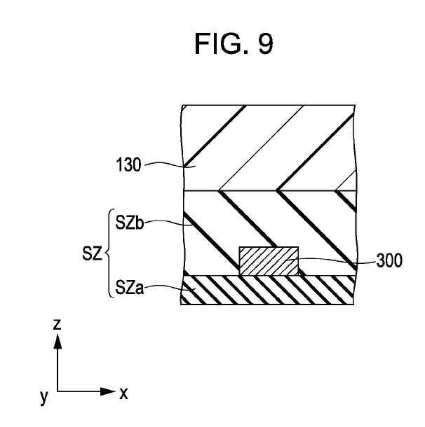

FIG. 9 is an enlarged cross-sectional view of a portion of the light shielding portion 300 according to the first embodiment. As shown in FIG. 9, the inter-layer insulating film SZ includes a silicon dioxide film SZa and a color filter contact layer SZb. The light shielding portion 300 is formed by patterning a metal film on the silicon dioxide film SZa, the surface thereof then being covered with the color filter contact layer SZb. The above-described color filter 130 is provided above the color filter contact layer SZb.

### B. Manufacturing Method

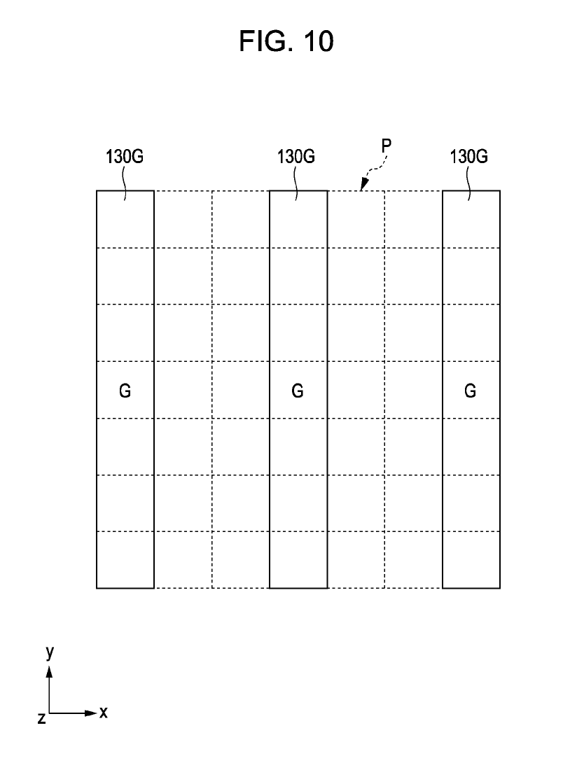

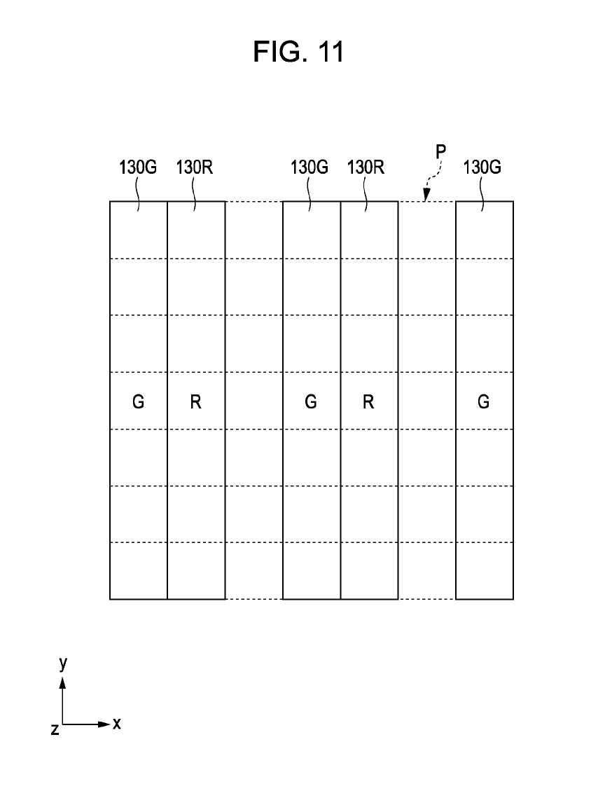

Next, principal parts of a manufacturing method for manufacturing the above-described solid-state imaging device 1 will be described. Here, the process for forming the color filter 130 of the solid-state imaging device 1 will be described in detail. FIGS. 10 and 11 are diagrams illustrating principal portions provided in the steps of the manufacturing method for manufacturing the solid-state imaging device 1, according to the first embodiment. FIGS. 10 and 11 illustrate the upper face, as with the case of FIG. 7.

### B-1. Formation of the Green Filter Layer 130G

First, the green filter layer 130G is formed as shown in FIG. 10, but before formation of the green filter layer 130G, the parts on the front face side of the substrate 101 are provided, and also the parts to be situated in layers beneath the green filter layer 130G on the rear face side of the substrate 101 are also formed. That is to say, as shown in FIG. 5 and other drawings, the parts such as the photodiodes 21, pixel transistors 50, light shielding portion 300, and so forth, are formed.

The light shielding portion 300 is formed so as to extend in the vertical direction y at the boundary portions of the multiple pixels arrayed in the horizontal direction x, as shown in FIG. 8. As shown in FIG. 9, the light shielding portion 300 is then covered with the inter-layer insulating film SZ, following which formation of the green filter layer 130G is performed.

Now, the green filter layer 130G is formed so as to extend covering the multiple pixels P extending in the vertical direction y, as shown in FIG. 10. Formation of the green filter layer 130G is performed using a photolithography technique, for example.

For example, first, application of a coating liquid including a green pigment and acrylic photoresist resin is performed by a coating method such as spin coating to form a coated film, which is pre-baked, so as to form an unshown photosensitive resin film. Next, exposure processing is performed, in which a pattern image such as that of the green filter layer 130G shown in FIG. 10 is exposed onto the photosensitive resin film. The photosensitive resin film which has been exposed is then developed, thereby patterning the photosensitive resin film into the green filter layer 130G.

### B-2. Formation of the Red Filter Layer 130R

Next, the red filter layer 130R is formed as shown in FIG. 11. Here, the red filter layer 130R is formed so as to extend covering the multiple pixels P extending in the vertical direction y, as shown in FIG. 11. Formation of the green filter layer 130G is performed using a photolithography technique, the same as with the case of the green filter layer 130G.

For example, first, application of a coating liquid including a red pigment and acrylic photoresist resin is performed by a coating method such as spin coating to form a coated film, which is pre-baked, so as to form an unshown photosensitive resin film. Next, exposure processing is performed, in which a pattern image such as that of the red filter layer 130R shown in FIG. 11 is exposed onto the photosensitive resin film. The photosensitive resin film which has been exposed is then developed, thereby patterning the photosensitive resin film into the red filter layer 130R as shown in FIG. 11.

### B-3. Formation of the Blue Filter Layer 130B

Next, the blue filter layer 130B is formed as shown in FIG. 7. Here, the blue filter layer 130B is formed so as to extend covering the multiple pixels P extending in the vertical direction y, as shown in FIG. 7. Formation of the blue filter layer 130B is performed using a photolithography technique, the same as with the case of the green filter layer 130G and the red filter layer 130R.

For example, first, application of a coating liquid including a blue pigment and acrylic photoresist resin is performed by a coating method such as spin coating to form a coated film, which is pre-baked, so as to form an unshown photosensitive resin film. Next, exposure processing is performed, in which a pattern image such as that of the blue filter layer 130B shown in FIG. 7 is exposed onto the photosensitive resin film. The photosensitive resin film which has been exposed is then developed, thereby patterning the photosensitive resin film into the blue filter layer 130B as shown in FIG. 7.

### B-4. Formation of Other Members

Subsequently, the smoothed film HT and on-chip lenses 140 are formed, thereby completing the solid-state imaging device 1. To form the smoothed film HT, for example, an acrylic thermal-hardening resin is coated on the upper face of the color filter 130 by spin coating, and then subjected to thermal processing, thereby forming the smoothed film HT.

Also, to form the on-chip lenses 140, for example, application of a photoresist resin is performed by spin coating to form a coated film on the smoothed film HT, which is baked, so as to form an unshown photosensitive resin film. Next, exposure processing and developing processing are performed in that order, thereby forming an unshown resist pattern with a rectangular cross-sectional form. This resist pattern is then subjected to reflow processing, thereby melting the resist pattern and forming semispherical on-chip lenses 140.

### C. Conclusion

As described above, with the present embodiment, the solid-state imaging device 1 is a backside illumination type in which the pixel transistors 50 and wiring portions 110 are provided on the opposite side of the substrate 101 from the photoreception face JS. The filter layers 130R, 130G, and 130B making up the color filter 130 are formed is as to extended in the vertical direction y above the photoreception face JS of the photodiodes 21 arrayed in the vertical direction y. Also, the filter layers 130R, 130G, and 130B are provided arrayed adjacently in the horizontal direction x. The light shielding portion 300 is formed at the boundary portions between the filter layers 130R, 130G, and 130B between the multiple photodiodes 21 arrayed in the horizontal direction x, so as to extend in the vertical direction y.

With the present embodiment, the filter layers 130R, 130G, and 130B extend in the vertical direction y, and each of the photodiodes 21 arrayed in the vertical direction y have light of the same color component input to the photoreception face JS. Accordingly, no color mixture occurs even if no light shielding portion 300 is provided at the boundary portions of the pixels P in the vertical direction y, so the area of the light shielding portion 300 can be reduced. This allows the aperture ratio of the pixels P to be raised, thereby readily enabling high sensitivity.

Particularly, in cases wherein the width of the aperture of the pixels P is 3 μm or smaller, the on-chip lenses do not function sufficiently in collecting light due to the diffraction effect of visible light, making high sensitivity difficult, but with the present embodiment, high sensitivity can be realized even in cases of forming fine pixels P. Accordingly, with the present embodiment, occurrence of color mixture can be prevented, and sensitivity can be raised, so the image quality of the imaged image can be improved.

### 2. Second Embodiment

### A. Configuration of Apparatus, etc.

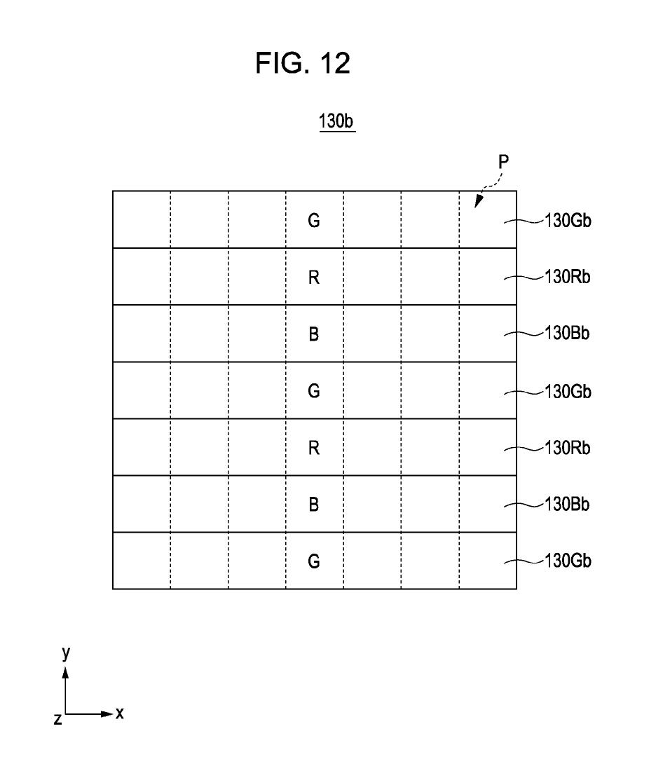

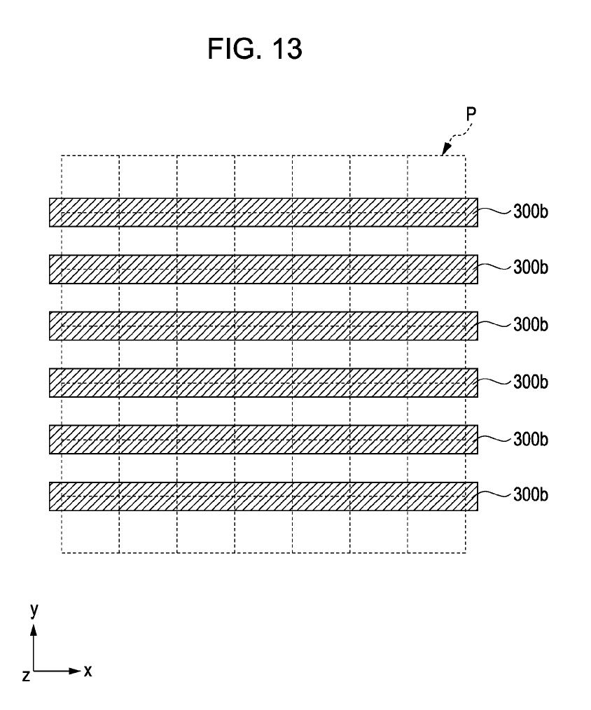

FIGS. 12 and 13 illustrate principal portions of a solid-state imaging device according to a second embodiment of the present invention. Here, FIG. 12 illustrates the upper face of a color filter 130b, in the same way as with FIG. 7. Also, FIG. 13 illustrates the upper face of a light shielding portion 300b, in the same way as with FIG. 8.

As shown in FIGS. 12 and 13, with the present embodiment, the color filter 130b differs from the color filter 130 in the first embodiment. Also, the light shielding portion 300b differs from the light shielding portion 300 in the first embodiment. Other than these and related points, the present embodiment is the same as with the first embodiment, so description of redundant portions will be omitted.

### A-1. About the Color Filter

As shown in FIG. 12, the color filter 130b is configured of a red filter layer 130Rb, a green filter layer 130Gb, and a blue filter layer 130Bb, much like the case of the first embodiment. The red filter layer 130Rb, green filter layer 130Gb, and blue filter layer 130Bb are arrayed in stripes according to color, as shown in FIG. 12, but with the present embodiment, the red filter layer 130Rb, green filter layer 130Gb, and blue filter layer 130Bb are arrayed on the horizontal direction x, unlike the case of the first embodiment. That is to say, the longitudinal direction of the red filter layer 130Rb, green filter layer 130Gb, and blue filter layer 130Bb is the horizontal direction x, rather than the vertical direction y.

Specifically, with the color filter 130b, the red filter layer 130Rb is formed so as to cover the multiple pixels P arrayed in the horizontal direction x as shown in FIG. 12. The red filter layer 130Rb is also positioned so as to be sandwiched between the green filter layer 130Gb on one side and the blue filter layer 130Bb on the other side in the vertical direction y.

Also, with the color filter 130b, the green filter layer 130Gb is formed so as to cover the multiple pixels P arrayed in the horizontal direction x as shown in FIG. 12, as with the case of the red filter layer 130Rb. The green filter layer 130Gb is also positioned so as to be sandwiched between the red filter layer 130Rb on one side and the blue filter layer 130Bb on the other side in the vertical direction y.

Further, with the color filter 130b, the blue filter layer 130Bb is formed so as to cover the multiple pixels P arrayed in the horizontal direction x as shown in FIG. 12, as with the case of the red filter layer 130Rb and green filter layer 130Gb. The blue filter layer 130Bb is also positioned so as to be sandwiched between the red filter layer 130Rb on one side and the green filter layer 130Gb on the other side in the vertical direction y.

### A-2. About the Light Shielding Portion

The light shielding portion 300b is formed in striped form in the same way as with the first embodiment, as shown in FIG. 13. However, the present embodiment differs from the first embodiment that the light shielding portion 300b extends in the horizontal direction x at the boundary portions of the multiple pixels P arrayed in the vertical direction y, with a plurality thereof being arrayed in the vertical direction y direction. The light shielding portion 300b is not provided at the boundary portion between the pixels P arrayed in the horizontal direction x. That is to say, a plurality of the light shielding portion 300b are arrayed in a direction perpendicular to the longitudinal direction in which the filter layers 130Rb, 130Gb, and 130Bb extend, i.e., in the y direction in which the filter layers 130Rb, 130Gb, and 130Bb are arrayed.

### B. Conclusion

As described above, with the present embodiment, the filter layers 130Rb, 130Gb, and 130Bb, making up the color filter 130b, extend in the horizontal direction x, above the photoreception face JS of the photodiodes 21 arrayed in the horizontal direction x. Also, the filter layers 130Rb, 130Gb, and 130Bb are provided so as to be arrayed adjacently in the vertical direction y. The light shielding portion 300b is formed so as to extend in the horizontal direction x at boundary portions of the filter layers 130Rb, 130Gb, and 130Bb, between the photodiodes 21 arrayed in the horizontal direction x.

With the present embodiment, the filter layers 130Rb, 130Gb, and 130Bb extend in the horizontal direction x, and each of the photodiodes 21 arrayed in the horizontal direction x have light of the same color component input to the photoreception face JS. Accordingly, no color mixture occurs even if no light shielding portion 300b is provided at the boundary portions of the pixels P in the horizontal direction x, so the area of the light shielding portion 300b can be reduced. This allows the aperture ratio of the pixels P to be raised, thereby readily enabling high sensitivity, as with the case of the first embodiment. Accordingly, with the present embodiment, occurrence of color mixture can be prevented, and sensitivity can be raised, so the image quality of the imaged image can be improved.

### 3. Third Embodiment

### A. Configuration of Apparatus, etc.

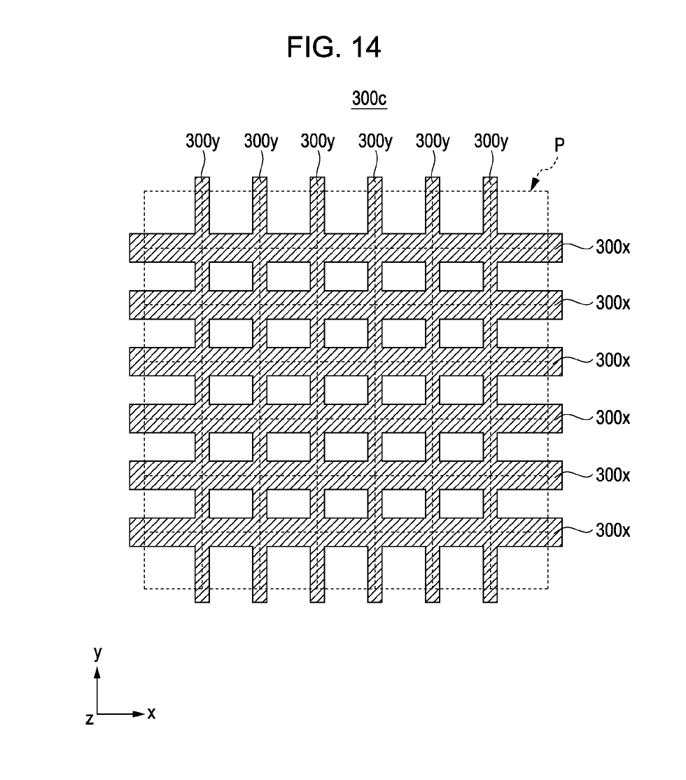

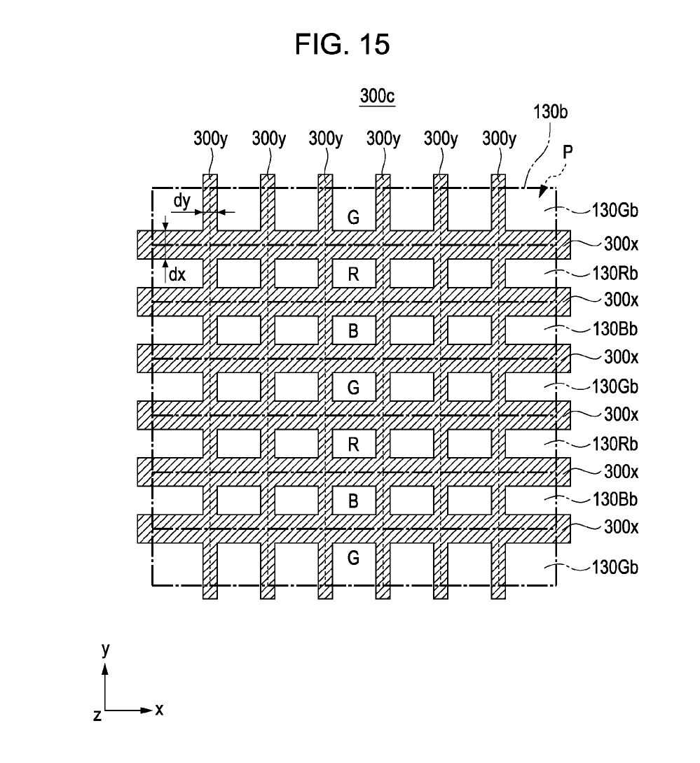

FIGS. 14 and 15 illustrate principal portions of a solid-state imaging device according to a third embodiment of the present invention. Here, FIG. 14 illustrates the upper face of a light shielding portion 300c, in the same way as with FIG. 13, and FIG. 14 shows FIG. 14 with the color filter 130b also included and indicated by single-dot broken lines.

As shown in FIGS. 14 and 15, with the present embodiment, the light shielding portion 300c differs from the light shielding portion 300b in the second embodiment. Other than this and related points, the present embodiment is the same as with the second embodiment, so description of redundant portions will be omitted.

The light shielding portion 300c includes portions 300x extending in the horizontal direction x as shown in FIG. 14, in the same way as with the second embodiment. The portions 300x of the light shielding portion 300c extending in the horizontal direction x are provided such that a plurality are arrayed at equal intervals in the vertical direction y at boundary portions of the pixels P arrayed in the vertical direction y.

However, unlike the second embodiment, the light shielding portion 300c also includes portions 300y extending in the vertical direction y besides the portions 300x extending in the horizontal direction x, as shown in FIG. 14. The portions 300y extending in the vertical direction y are provided such that a plurality are arrayed at equal intervals in the horizontal direction x at boundary portions of the pixels P arrayed in the horizontal direction x. That is to say, as shown in FIG. 14, with the light shielding portion 300c, the portions 300x extending in the horizontal direction x and the portions 300y extending in the vertical direction y intersect each other, to form a grid.

As shown in FIG. 15, above the light shielding portion 300c is formed the color filter 130b, in the same way as with the second embodiment. The color filter 130b includes the red filter layer 130Rb, green filter layer 130Gb, and blue filter layer 130Bb, with the filter layers 130Rb, 130Gb, and 130Bb extending on the horizontal direction x. That is to say, for each of the filter layers 130Rb, 130Gb, and 130Bb, the longitudinal direction is the horizontal direction x rather than the vertical direction y.

As shown in FIG. 15, the light shielding portion 300c is formed such that a width dy of the portions 300y extending in the vertical direction y is narrower than a width dx of the portions 300x extending in the horizontal direction x. That is to say, regarding the extending portions 300x and 300y of the light shielding portion 300c, the width of the extending portions 300y of which a plurality are arrayed in the longitudinal direction in which the filter layers 130Rb, 130Gb, and 130Bb extend is narrower than the width of the other extending portions 300x.

### B. Conclusion

As described above, with the present embodiment, the color filter 130b is formed in the same way as with the second embodiment. The light shielding portion 300c includes portions 300x which are formed so as to extend in the horizontal direction x at boundary portions of the filter layers 130Rb, 130Gb, and 130Bb, in the same way as with the second embodiment. Also, the light shielding portion 300c further includes portions 300y which are formed so as to extend in the vertical direction y at boundary portions of the multiple photodiodes arrayed in the vertical direction y. Moreover, with the present embodiment, the width of the portions 300x extending in the horizontal direction x is formed so as to be wider than the width of the portions 300y extending in the vertical direction y.

With the present embodiment, the filter layers 130R, 130G, and 130B extend in the horizontal direction x, and each of the photodiodes 21 arrayed in the horizontal direction x have light of the same color component input to the photoreception face JS, as with the case of the second embodiment. On the other hand, the filter layers 130R, 130G, and 130B are sequentially arrayed in the vertical direction y. Accordingly, little color mixture occurs between pixels P as compared with the vertical direction y, so the area of the light shielding portion 300c can be reduced. This allows the aperture ratio of the pixels P to be raised as with the case of the second embodiment, thereby readily enabling high sensitivity. Accordingly, with the present embodiment, occurrence of color mixture can be prevented, and sensitivity can be raised, so the image quality of the imaged image can be improved.

### 4. Fourth Embodiment

### A. Configuration of Apparatus, etc.

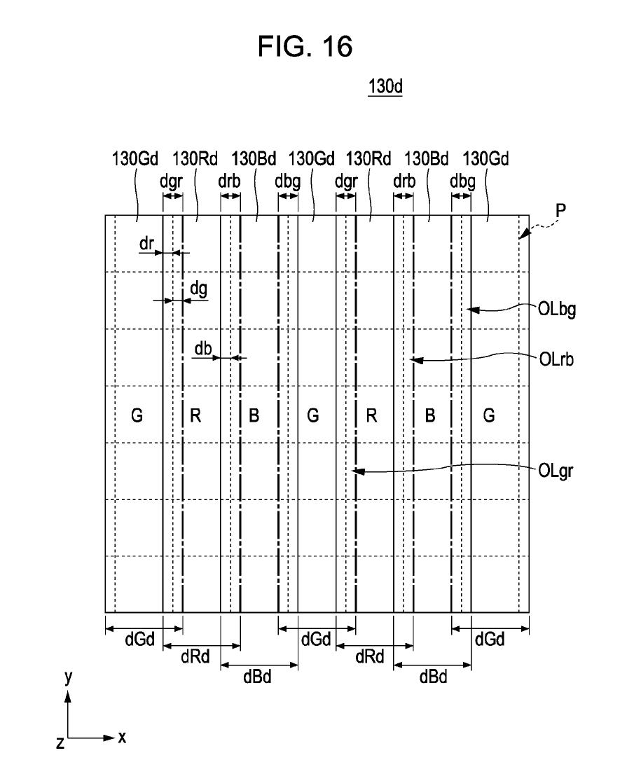

FIG. 16 illustrates principal portions of a solid-state imaging device according to a fourth embodiment of the present invention. Here, FIG. 16 illustrates the upper face of a color filter 130d, in the same way as with FIG. 7. FIG. 16 shows edge portions of upper layer portions with heavy solid lines, and edge portions of lower layer portions with heavy dotted lines. As shown in FIG. 16, with the present embodiment, the color filter 130d differs from the color filter 130 in the first embodiment. Other than this and related points, the present embodiment is the same as with the first embodiment, so description of redundant portions will be omitted.

As shown in FIG. 16, the color filter 130d includes a red filter layer 130Rd, green filter layer 130Gd, and blue filter layer 130Bd, in the same way as with the first embodiment. The red filter layer 130Rd, green filter layer 130Gd, and blue filter layer 130Bd are formed extending in the vertical direction y. However, unlike the case of the first embodiment, the red filter layer 130Rd, green filter layer 130Gd, and blue filter layer 130Bd are each formed overlapping with other filter layers. Also, the widths of the red filter layer 130Rd, green filter layer 130Gd, and blue filter layer 130Bd are formed such that the widths dGd, dRd, and dBd, respectively, defined in the horizontal direction x, are formed so as to be wider than the widths of the pixels P, that is to say, dGd=dRd=dBd.

Specifically, the green filter layer 130Gd is formed so as to overlap a portion of a red filter layer 130Rd or blue filter layer 130Bb in the horizontal direction x, thereby forming overlapped regions OLgr and OLbg. Here, we will say that in the overlapped regions OLgr and OLbg, a red filter layer 130Rd or blue filter layer 130Bd is overlaid on the green filter layer 130Gd.

Also, the red filter layer 130Rd is formed so as to overlap a portion of a green filter layer 130Gd or blue filter layer 130Bb in the horizontal direction x, thereby forming overlapped regions OLgr and OLrb. Here, we will say that in the overlapped region OLgr, a green filter layer 130Gd is layered so as to be situated under the red filter layer 130Rd. Also, in the overlapped region OLrb, a blue filter layer 130Bd is layered so as to be situated above the red filter layer 130Rd.

Further, the blue filter layer 130Bd is formed so as to overlap a portion of a red filter layer 130Rd or green filter layer 130Gd in the horizontal direction x, thereby forming overlapped regions OLrb and OLbg. Here, we will say that in the overlapped region OLrb, a red filter layer 130Rd is layered so as to be situated under the blue filter layer 130Bd. Also, in the overlapped region OLbg, a green filter layer 130Gd is layered so as to be situated below the blue filter layer 130Bd.

Thus, the color filter 130d according to the present embodiment includes overlapped regions OLgr, OLrb, and OLbg, where the filter layers 130Rd, 130Gd, and 130Bd of different colors overlap in the horizontal direction x. The overlapping widths dg, dr, and db of the filter layers 130Rd, 130Gd, and 130Bd upon other adjacent pixels in the horizontal direction x are formed so as to be the same.

### B. Manufacturing Method

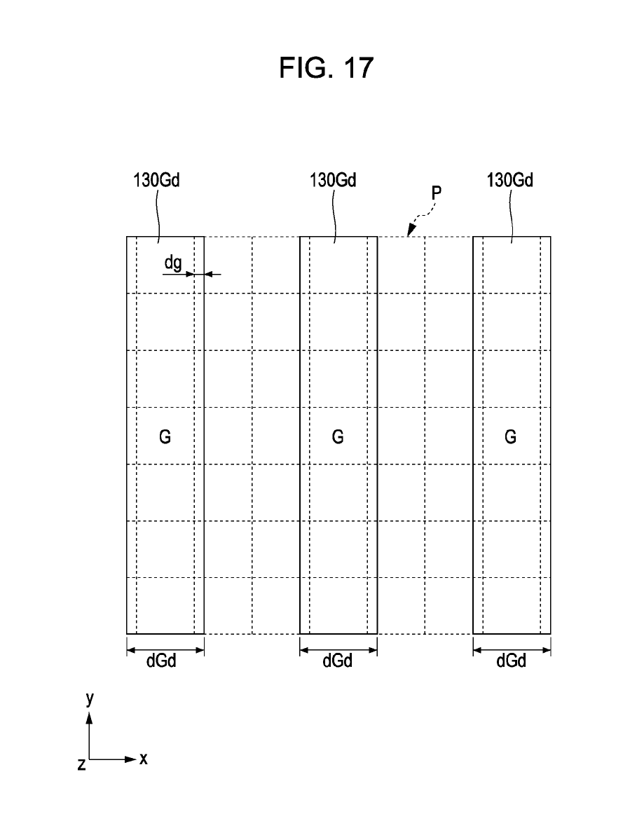

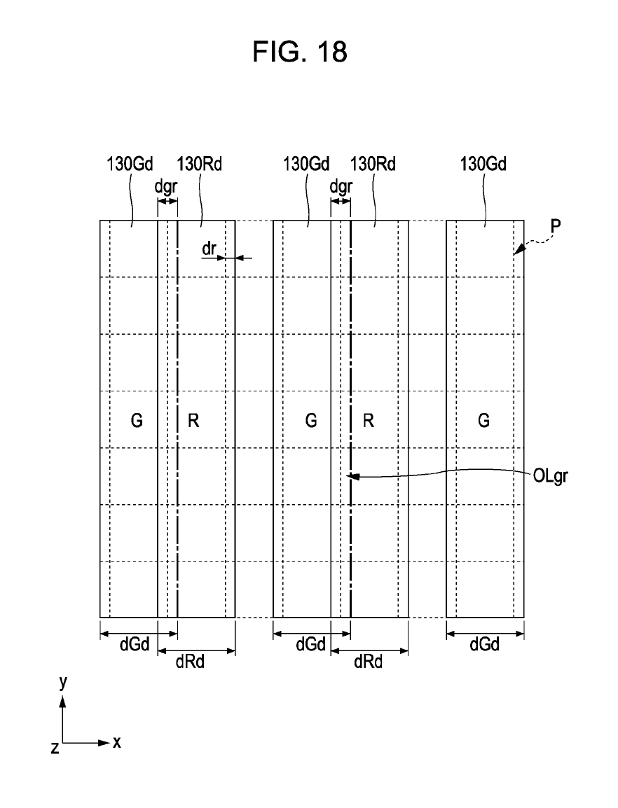

Next, principal parts of a manufacturing method for manufacturing the above-described solid-state imaging device will be described. Here, the process for forming the color filter 130d of the solid-state imaging device will be described in detail. FIGS. 17 and 18 are diagrams illustrating principal portions provided in the steps of the manufacturing method for manufacturing the solid-state imaging device according to the present embodiment. FIGS. 17 and 18 illustrate the upper face, as with the case of FIG. 16.

### B-1. Formation of the Green Filter Layer

First, the green filter layer 130Gd is formed as shown in FIG. 17. The green filter layer 130Gd is formed so as to extend covering the multiple pixels P extending in the vertical direction y, as shown in FIG. 17, in the same way as with the first embodiment. Formation of the green filter layer 130Gd is performed using a photolithography technique, for example, in the same way as with the first embodiment. Unlike the case of the first embodiment though, with the present embodiment, the green filter layer 130Gd is formed such that the width dGd of the green filter layer 130Gd is wider than the width of the pixels P.

### B-2. Formation of the Red Filter Layer

Next, the red filter layer 130Rd is formed as shown in FIG. 18. The red filter layer 130Rd is formed so as to extend covering the multiple pixels P extending in the vertical direction y, as shown in FIG. 18. Formation of the red filter layer 130Rd is performed using a photolithography technique, for example, in the same way as with the first embodiment.

Unlike the case of the first embodiment though, with the present embodiment, the red filter layer 130Rd is formed such that the width dRd of the red filter layer 130Rd is wider than the width of the pixels P. Also, the red filter layer 130Rd is formed so as to partially overlap the green filter layer 130Gd in the horizontal direction x. This forms the overlapped region OLgr where the red filter layer 130Rd and green filter layer 130Gd overlap, as shown in FIG. 18.

### B-3. Formation of the Blue Filter Layer

Next, the blue filter layer 130Bd is formed as shown in FIG. 16. The blue filter layer 130Bd is formed so as to extend covering the multiple pixels P extending in the vertical direction y, as shown in FIG. 18. Formation of the blue filter layer 130Bd is performed using a photolithography technique, for example, in the same way as with the first embodiment.

Unlike the case of the first embodiment though, with the present embodiment, the blue filter layer 130Bd is formed such that the width dBd of the blue filter layer 130Bd is wider than the width of the pixels P. Also, the blue filter layer 130Bd is formed so as to partially overlap the green filter layer 130Gd or red filter layer 130Rd in the horizontal direction x. This forms the overlapped region OLrb where the red filter layer 130Rd and blue filter layer 130Bd overlap, and the overlapped region OLbg where the green filter layer 130Gd and blue filter layer 130Bd overlap, as shown in FIG. 16.

### C. Conclusion

As described above, with the present embodiment, the filter layers 130Rd, 130Gd, and 130Bd making up the color filter 130d extend in the vertical direction y over the photoreception face JS of the photodiodes 21 arrayed in the vertical direction y, in the same way as with the first embodiment. Also, the filter layers 130Rd, 130Gd, and 130Bd are provided so as to have overlapping portions at the boundary portion between the multiple photodiodes 21 arrayed in the horizontal direction x, i.e., between the pixels P.

Accordingly, incident light input at an angle in the horizontal direction x passes through filter layers of multiple colors at the overlapped portions of the filter layers 130Rd, 130Gd, and 130Bd, i.e., the overlapped regions OLbg, OLrb, and OLgr. Thus, with the present embodiment, color mixing occurring between pixels P arrayed in the horizontal direction x can be effectively prevented. Accordingly, with the present embodiment, occurrence of color mixing can be prevented, and sensitivity can be improved, so the image quality of imaged images can be improved.

Note that with the present embodiment, the filter layers 130Rd, 130Gd, and 130Bd have the same overlapped widths dg, dr, and db above other adjacent pixels P in the horizontal direction x, but the present embodiment is not restricted to this arrangement, and the widths dg, dr, and db may differ. In this case, it is preferable that the width dr by which the red filter layer 130Rd overlaps other adjacent pixels P in the horizontal direction x is wider than the width dg of the green filter layer 130Gd. It is also preferable that the width dg by which the green filter layer 130Gd overlaps other adjacent pixels P in the horizontal direction x is wider than the width db of the blue filter layer 130Bd. That is to say, it is preferable that a filter layer which transmits light with a higher wavelength overlaps other adjacent pixels P in the horizontal direction x with a width wider than the width thereof of a filter layer which transmits light with a lower wavelength. This is because light with a higher wavelength exhibits higher photoreception sensitivity than light with a lower wavelength, resulting in more occurrence of trouble due to color mixing.

### 5. Fifth Embodiment

### A. Configuration of Apparatus, etc.

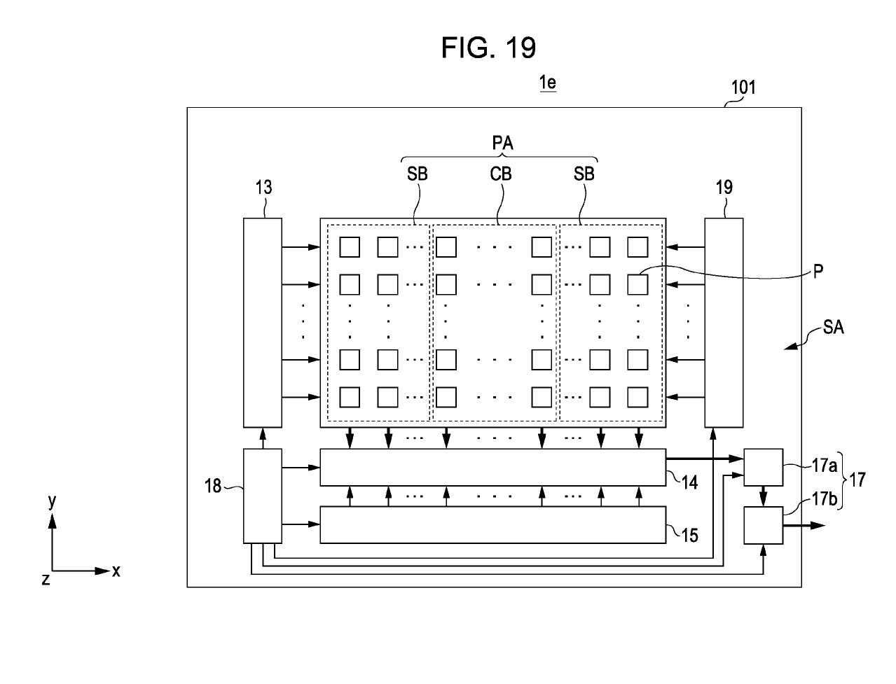

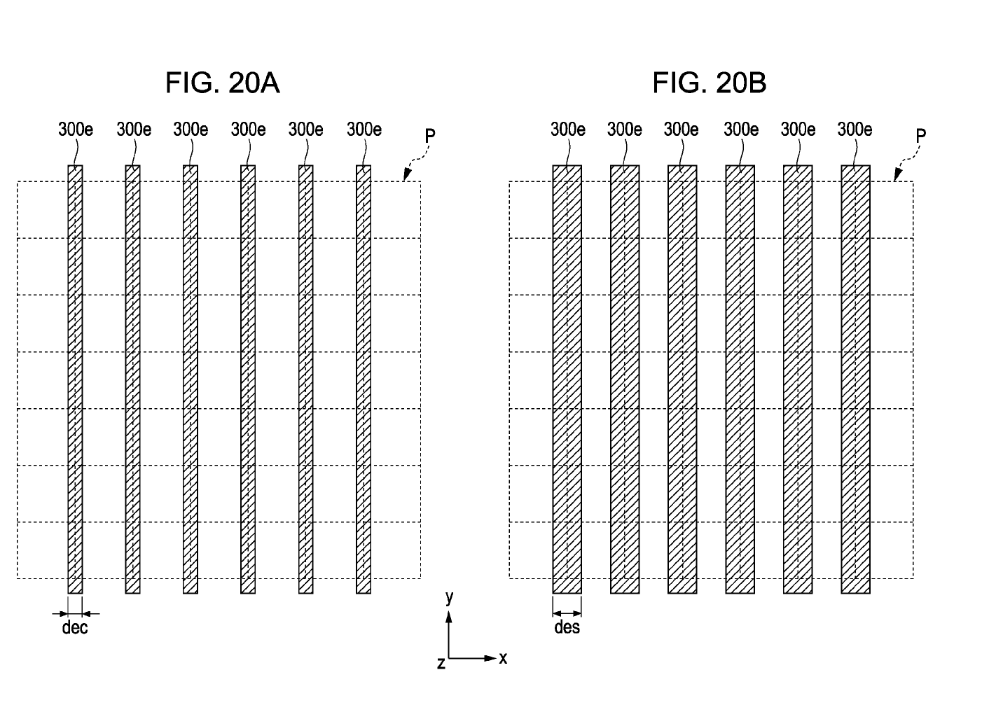

FIGS. 19 through 20B illustrate principal portions of a solid-state imaging device according to a fifth embodiment of the present invention. Here, FIG. 19 is a block diagram illustrating the overall configuration of a solid-state imaging device 1e, in the same way as with FIG. 2. FIG. 20A illustrates a middle portion CB of the imaging region PA shown in FIG. 19, and FIG. 20B illustrates a side portion SB of the imaging region PA shown in FIG. 19. As shown in FIGS. 19 through 20B, with the present embodiment, the light shielding portion 300e differs from the light shielding portion 300 in the first embodiment. Other than this and related points, the present embodiment is the same as with the first embodiment, so description of redundant portions will be omitted.

The solid-state imaging device 1e according to the present embodiment is a CMOS image sensor as with the case of the first embodiment, and includes a substrate 101 as shown in FIG. 19. The face of the substrate 101 is provided with an imaging region PA and periphery region SA. However, unlike the case of the first embodiment, the imaging region PA is sectioned into a middle portion CB and side portions SB.

In the imaging region PA, the middle portion CB is at the middle portion in the horizontal direction x as shown in FIG. 19. Accordingly, primary rays at an angle approximately perpendicular to the face of the imaging region PA (H1 in FIG. 1) are input to the pixels P in the middle portion CB. On the other hand, in the imaging region PA, side portions SB are provided sandwiching the middle portion CB in the horizontal direction x. Accordingly, primary rays at an inclined angle as to those perpendicular to the face of the imaging region PA (H2 in FIG. 1) are input to the pixels P in the side portions SB.

As shown in FIGS. 20A and 20B, the light shielding portion 300e extends in the vertical direction y at the boundary portions of multiple pixels P arrayed in the horizontal direction x, with a plurality thereof arrayed at equal intervals in the horizontal direction x. However, as can be seen by comparing FIGS. 20A and 20B, the light shielding portion 300e according to the present embodiment is formed such that the width dec of portions extending in the vertical direction y in the middle portion CB is narrower than the width des of portions extending in the vertical direction y in the side portions SB.

### B. Conclusion

As described above, with the present embodiment, a color filter 130 is provided, as with the case of the first embodiment. Also, the light shielding portion 300e is formed so as to extend in the vertical direction y at the boundary portions of the filter layers 130R, 130G, and 130B, as with the case of the first embodiment. In this arrangement, the light shielding portion 300e is formed such that the width of portions extending in the vertical direction y are broader farther away from the center of the imaging face (x-y) face.

As described above, at the side portions SB, primary rays with an inclined angle (H2 in FIG. 1) are input, so color mixing occurs more often than at the middle portion CB. Accordingly, trouble due to anisotropy of color mixing occurs more readily at the side portions SB than at the middle portion CB. However, with the present embodiment, the width of the light shielding portion 300e is broader at the side portions SB than at the middle portion CB of the imaging region PA, thereby making occurrence of color mixing more uniform at the side portions SB and the middle portion CB. Thus, in addition to the advantages of the first embodiment, the present embodiment can improve image quality by effectively preventing occurrence of shading.

While an arrangement has been described here wherein the imaging region PA is divided into a middle portion CB and two side portions SB, with the width of the light shielding portion 300e differing therebetween, the present embodiment is not restricted to this arrangement. For example, an arrangement may be made wherein the imaging region PA is sectioned into three or more portions, with the width of the light shielding portion 300e differing at each.

### 6. Sixth Embodiment

### A. Configuration of Apparatus, etc.

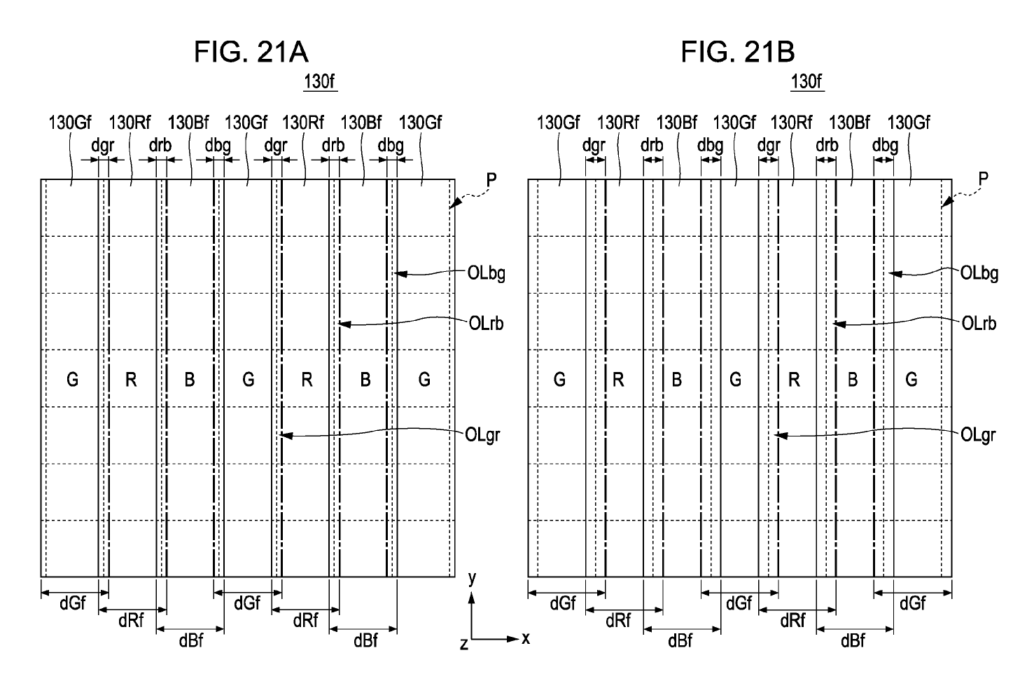

FIGS. 21A and 21B illustrate principal portions of a solid-state imaging device if according to a sixth embodiment of the present invention. Here, FIGS. 21A and 21B illustrate the upper face of the color filter 130f, in the same way as with FIG. 7. FIG. 21A illustrates the middle portion CB of the imaging region PA shown in FIG. 19, and FIG. 21B illustrates a side portion SB of the imaging region PA shown in FIG. 19. As shown in FIGS. 21A and 21B, with the present embodiment, the color filter 130f differs from the color filter in the fifth embodiment. Other than this and related points, the present embodiment is the same as with the fifth embodiment, so description of redundant portions will be omitted.

As shown in FIGS. 21A and 21B, the color filter 130f includes a red filter layer 130Rf, a green filter layer 130Gf, and a blue filter layer 130Bf, as with the case of the first embodiment. The red filter layer 130Rf, green filter layer 130Gf, and blue filter layer 130Bf are each formed so as to extend in the vertical direction y. However, unlike the case of the first embodiment, red filter layer 130Rf, green filter layer 130Gf, and blue filter layer 130Bf are each formed so that a portion thereof overlaps another filter layer. Also, the widths of the red filter layer 130Rf, green filter layer 130Gf, and blue filter layer 130Bf are formed such that the widths dGf, dRf, and dBf, respectively, defined in the horizontal direction x, are formed so as to be wider than the widths of the pixels P, that is to say, dGf=dRf=dBf, as with the case of the fourth embodiment.

It can be seen by comparing FIGS. 21A and 21B that the configuration of the color filter 130f differs between the middle portion CB (FIG. 21A) and side portions (FIG. 21B). Specifically, it can be seen by comparing FIGS. 21A and 21B that the widths dGf, dRf, and dBf, of the filter layers 130R, 130Gf, and 130Bf are narrower in the middle portion CB than at the side portions SB. Further, it can be seen by comparing FIGS. 21A and 21B that the widths dgr, drb, and dgb, of the overlapped regions OLbg, OLrb, and OLgr of the filter layers 130R, 130Gf, and 130Bf are narrower in the middle portion CB than at the side portions SB.

### B. Conclusion

As described above, with the present embodiment, the filter layers 130R, 130Gf, and 130Bf making up the color filter 130f extend in the vertical direction y direction above the photoreception face JS of the photodiodes 21 arrayed on the vertical direction y, in the same way as with the fifth embodiment. The filter layers 130R, 130Gf, and 130Bf are provided so as to include a portion overlapping with others at the boundary portion of the multiple photodiodes 21 arrayed in the horizontal direction x, i.e., between the pixels P. Further, in this arrangement, the area of overlapping of the filter layers 130R, 130Gf, and 130Bf is greater the farther away from the center of the imaging face (x-y) face.

As described with the fifth embodiment, occurrence of color mixing differs between the side portions SB and the middle portion CB. However, with the present embodiment, area of overlapping of the filter layers 130R, 130Gf, and 130Bf is greater at the side portions SB than at the middle portion CB of the imaging region PA, thereby making occurrence of color mixing more uniform at the side portions SB and the middle portion CB. Thus, in addition to the advantages of the first embodiment, the present embodiment can improve image quality by effectively preventing occurrence of shading.

While an arrangement has been described here wherein the imaging region PA is divided into a middle portion CB and two side portions SB, with the area of overlapping of the filter layers 130R, 130Gf, and 130Bf differing therebetween, the present embodiment is not restricted to this arrangement. For example, an arrangement may be made wherein the imaging region PA is sectioned into three or more portions, with the width of the light shielding portion 300e differing at each.

### 7. Seventh Embodiment

### A. Configuration of Apparatus, etc.

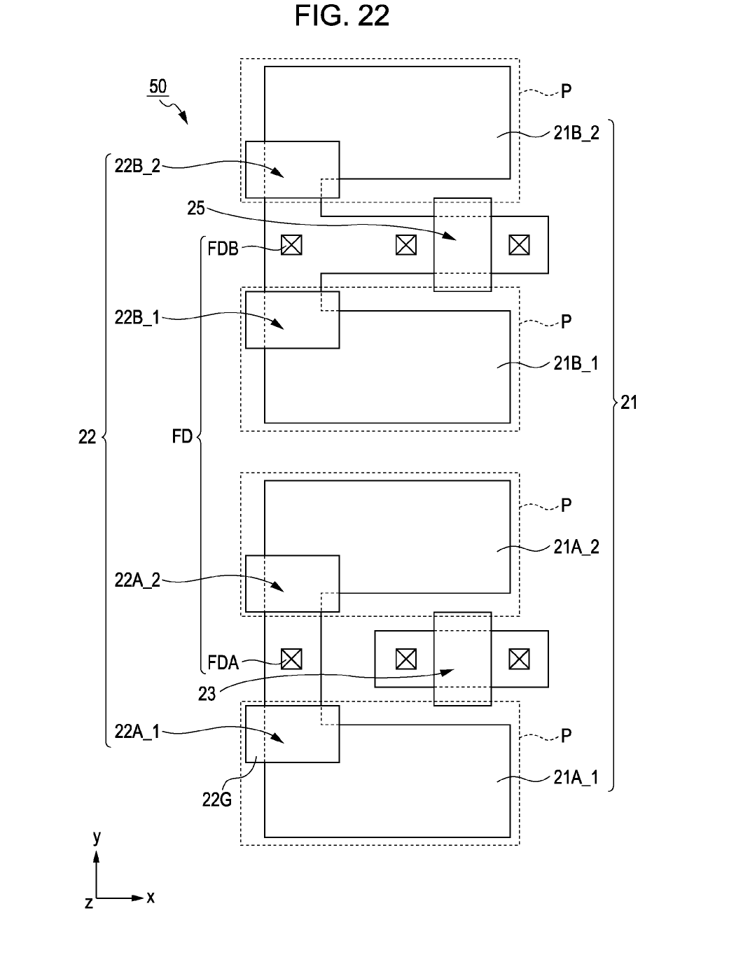

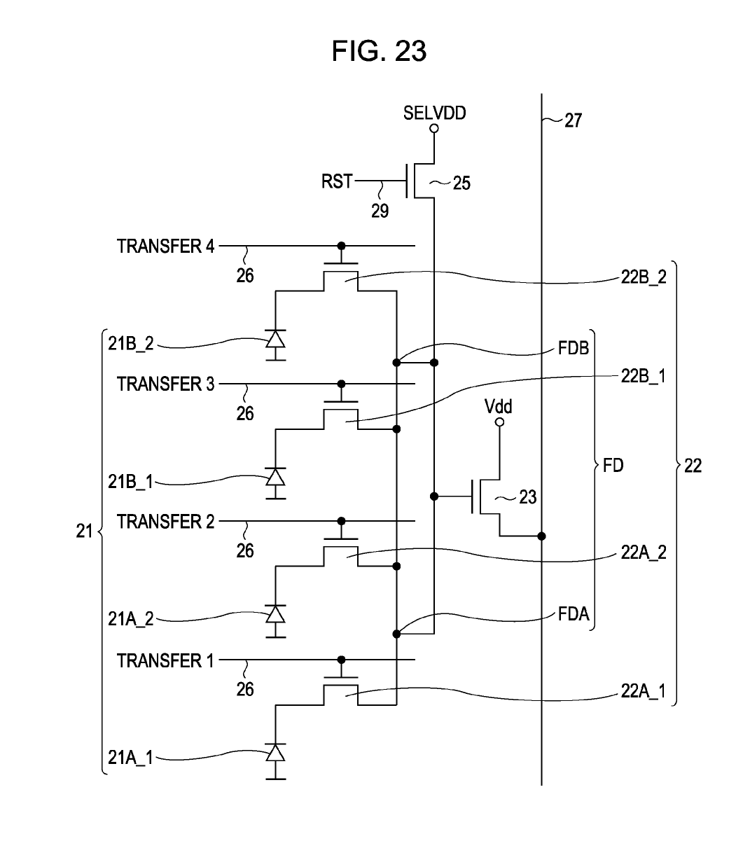

FIGS. 22 and 23 illustrate principal portions of a solid-state imaging device according to a seventh embodiment of the present invention. FIG. 22 schematically illustrates the upper face of pixels P, the same as with FIG. 6, and FIG. 23 illustrates the circuit configuration. As shown in FIGS. 22 and 23, the placement of members making up pixels P, and the circuit configuration thereof, differ from the first embodiment. Other than these and related points, the present embodiment is the same as with the first embodiment, so description of redundant portions will be omitted.

As shown in FIGS. 22 and 23, the solid-state imaging device according to the present embodiment includes photodiodes 21 and pixel transistors 50, the same as with the first embodiment. The members will be described in order.

### A-1. About the Photodiodes 21

Multiple photodiodes 21 are provided as shown in FIG. 22, corresponding to each of the multiple pixels P, as with the case of the first embodiment. As shown in FIGS. 22 and 23, with the present embodiment, transfer transistors 22 are provided to the photodiodes 21. More specifically, as shown in FIGS. 22 and 23, four transfer transistors 22 (22A_1, 22A_2, 22B_1, 22B_2) are provided corresponding to four photodiodes 21 (21A_1, 21A_2, 21B_1, 21B_2), in a one-to-one manner.

Further, as shown in FIGS. 22 and 23, multiple photodiodes 21 are arranged to share a single floating diffusion FD. Here, one set of photodiodes 21 arrayed in the vertical direction y (21A_1 and 21A_2, or 21B_1 and 21B_2) are provided to a single floating diffusion FD (FDA or FDB).

Also, as shown in FIGS. 22 and 23, a set of multiple photodiodes 21 is arranged to share the amplifier transistor 23 and reset transistor 25. Here, one amplifier transistor 23 and one reset transistor 25 are provided to a set of four photodiodes 21 arrayed in the vertical direction y (21A_1, 21A_2, 21B_1, and 21B_2).

Specifically, as shown in FIG. 22, the floating diffusion FDA is provided at the left portion between the photodiodes 21A_1 and 21A_2 to the lower side. The transfer transistors 22A_1 and 22A_2 are provided between the photodiodes 21A_1 and 21A_2 and the floating diffusion FDA, respectively. The amplifier transistor 23 is provided to the right side portion between the photodiodes 21A1 and 21A_2.

Also, as shown in FIG. 22, the floating diffusion FDB is provided at the left portion between the photodiodes 21B_1 and 21B_2 to the upper side. The transfer transistors 22B_1 and 22B_2 are provided between the photodiodes 21B_1 and 21B_2 and the floating diffusion FDB, respectively. The reset transistor 25 is provided to the right side portion between the photodiodes 21B_1 and 21B_2.

### A-2. About the Pixel Transistor 50

As shown in FIGS. 22 and 23, the pixel transistor 50 includes transfer transistors 22, the amplifier transistor 23, and the reset transistor 25. With the present embodiment, a selection power source SELVDD is provided instead of the selecting transistor.

With the pixel transistor 50, multiple transfer transistors 22 are provided so as to correspond to the multiple pixels P, as shown in FIGS. 22 and 23. Here, as shown in FIG. 22, two transfer transistors 22A_1 and 22A_2 arrayed in the vertical direction y sandwich the floating diffusion FDA provided between the two photodiodes 21A_1 and 21A_2. As shown in FIG. 23, the two transfer transistors 22A_1 and 22A_2 are configured to transfer signal charges from the photodiode 21A_1 and 21A_2, respectively, to the floating diffusion FDA. That is to say, each of the transfer transistors 22A_1 and 22A_2 is electrically connected to a transfer line 26, input transfer signals to transfer the signal charge to the floating diffusion FDA.

Also, above this, as shown in FIG. 22, two transfer transistors 22B_1 and 22B_2 arrayed in the vertical direction y sandwich the floating diffusion FDB provided between the two photodiodes 21B_1 and 21B_2. As shown in FIG. 23, the two transfer transistors 22B_1 and 22B_2 are configured to transfer signal charges from the photodiode 21B_1 and 21B_2, respectively, to the floating diffusion FDB. That is to say, each of the transfer transistors 22B_1 and 22B_2 is electrically connected to a transfer line 26, input transfer signals to transfer the signal charge to the floating diffusion FDB.

With the pixel transistor 50, each of the amplifier transistor 23 and reset transistor 25 are shared by a set of multiple photodiodes 21, as shown in FIGS. 22 and 23. That is to say, as shown in FIGS. 22 and 23, one amplifier transistor 23 and one reset transistor 25 are provided as to a set of four photodiodes 21 (21A_1, 21A_2, 21B_1, and 21B_2).

Note that, as shown in FIG. 23, the gate of the amplifier transistor 23 is electrically connected to the floating diffusions FDA and FDB, the source is electrically connected to the vertical signal line 27, and the drain is electrically connected to the fixed power source Vdd. Also, as shown in FIG. 23, the gate of the reset transistor 25 is electrically connected to the reset line 29 by which reset signals RST are supplied, the source is electrically connected to the floating diffusions FDA and FDB, and the drain is electrically connected to the selection power source SELVDD. The selection power source SELVDD selects pixels P by switching the voltage level, in the same way as with selection pulses.

### A-3. Operations

The operations of the solid-state imaging device according to the present embodiment will be described. With the present embodiment, signal charges generated at multiple photodiode 21 are added at the floating diffusion FD and output. That is to say, what is called “floating diffusion addition” is performed.

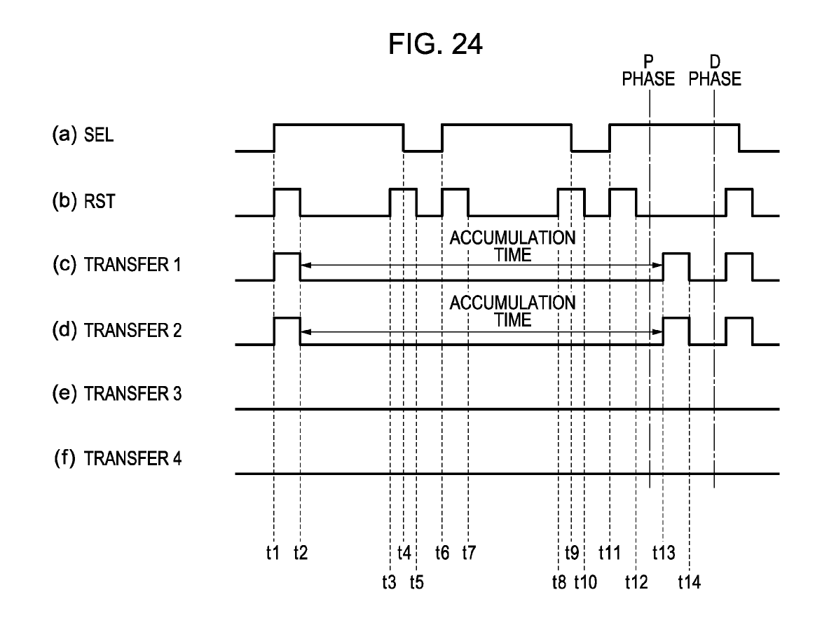

FIG. 24 is a timing chart illustrating the operations of the solid-state imaging device according to the seventh embodiment of the present invention. In FIG. 24, (a) represents the potential of selection power source (SEL), (b) represents the reset signal (RST), and (c) through (f) represents transfer signals (transfer 1, 2, 3, and 4). Note that (c) represents the transfer signal (transfer 1) to be input to the gate of the transfer transistor 22A_1, (d) represents the transfer signal (transfer 2) to be input to the gate of the transfer transistor 22A_2, (e) represents the transfer signal (transfer 3) to be input to the gate of the transfer transistor 22B_1, and (f) represents the transfer signal (transfer 4) to be input to the gate of the transfer transistor 22B_2.

First, as shown in FIG. 24, at a first point-in-time t1, the potential (SEL) of the selection power source SELVDD goes from low level to high level. Also, the reset signal (RST) is set to high level, so that the reset transistor 25 goes on. Along with this, the transfer signals (transfer 1 and transfer 2) are set to high level, so that the two transfer transistors 22A_1 and 22A_2 go on. Thus, an “electronic shutter operation” where the charges of the photodiodes 21A_1 and 21A_2 are discharged and emptied is performed.

At a second point-in-time t2, the reset signal (RST) and transfer signals (transfer 1 and transfer 2) are set to low level as shown in FIG. 24, so that the reset transistor 25 and the two transfer transistors 22A_1 and 22A_2 go off.

As shown in FIG. 24, the accumulation period is then entered. During the accumulation period, the photodiodes 21 receive light and generate signal charges. The photodiodes 21 accumulate signal charges according to the amount of light received.

During the accumulation period, at a third point-in-time t3, the reset signal (RST) is set to high level, so that the reset transistor 25 goes on. At a fourth point-in-time t4, the potential (SEL) of the selection power source SELVDD goes from high level to low level. Subsequently, at a fifth point-in-time t5, the reset signal (RST) is set to low level, so that the reset transistor 25 goes off.

The operations from the third point-in-time t3 through the fifth point-in-time t5 are resetting operations for other shared units irrelevant to this shared unit, and are backfill operations.

Next, as shown in FIG. 24, at a sixth point-in-time t6, selection power source SELVDD goes from low level to high level. At the same time, the reset signal (RST) is set to high level, so that the reset transistor 25 goes on. At a seventh point-in-time t7, the reset signal (RST) is set to low level, so that the reset transistor 25 goes off.

During the accumulation period, as shown in FIG. 24, at an eighth point-in-time t8, the reset signal (RST) is set to high level, so that the reset transistor 25 goes on. At a ninth point-in-time t9, the potential (SEL) of the selection power source SELVDD goes from high level to low level. Subsequently, at a tenth point-in-time t10, the reset signal (RST) is set to low level, so that the reset transistor 25 goes off.

The operations from the eighth point-in-time t8 through the tenth point-in-time t10 are resetting operations for other shared units irrelevant to this shared unit, and are backfill operations.

Next, as shown in FIG. 24, at an eleventh point-in-time t11, selection power source SELVDD goes from low level to high level. At the same time, the reset signal (RST) is set to high level, so that the reset transistor 25 goes on. At a twelfth point-in-time t12, the reset signal (RST) is set to low level, so that the reset transistor 25 goes off.

Thus, the potential of the floating diffusion FD is reset. As shown in FIG. 24, a signal is output at the potential at the time of resetting, in P phase (preset phase). That is to say, voltage corresponding to the reset level is read out to the column circuit 14 (see FIG. 2).

Next, as shown in FIG. 24, at a thirteenth point-in-time t13, the transfer signals (transfer 1 and transfer 2) are set to high level, so that the two transfer transistors 22A_1 and 22A_2 go on. After a predetermined amount of time elapses, at a fourteenth point-in-time t14, transfer signals (transfer 1 and transfer 2) are set to low level, so that the two transfer transistors 22A_1 and 22A_2 go off.

Thus, the signal charges accumulated in the two photodiodes 21A_1 and 21A_2 are transferred to the floating diffusion FDA. As shown in FIG. 24, a signal is output at the potential of the floating diffusion FDA, in D phase (data phase). That is to say, voltage of a signal level corresponding to the signal charges accumulated in the two photodiodes 21A_1 and 21A_2 is read out to the column circuit 14.

Subsequently, in the same way as with the first embodiment, the column circuit 14 performs difference processing regarding the reset level read out first, and the signal level read out later. Accordingly, fixed pattern noise generated due to irregularities in the threshold voltage Vth of the transistors provided at each pixel P is cancelled out from the pixel signals. Signals accumulated at the column circuit 14 are selected by the horizontal driving circuit 15, and sequentially output to the external output circuit 17 (see FIG. 2). Thus, driving of the solid-state imaging device is performed by FD addition.

Note that while a case of performing FD addition between the two photodiodes 21A_1 and 21A_2 has been described here, the present embodiment is not restricted to this arrangement. For example, FD addition may be performed among four photodiodes 21A_1, 21A_2, 21B_1, and 21B_2.

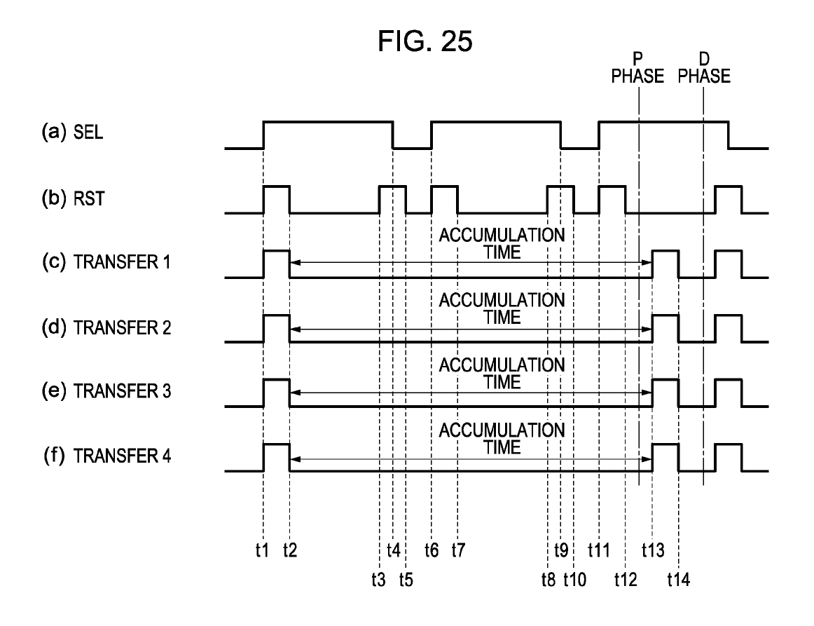

FIG. 25 is a timing chart illustrating operations of the solid-state imaging device in a modification of the seventh embodiment. FIG. 25 illustrates a case of performing FD addition among the four photodiodes 21A_1, 21A_2, 21B_1, and 21B_2.

In FIG. 25, (a) represents the potential of selection power source (SEL), (b) represents the reset signal (RST), and (c) through (f) represents transfer signals (transfer 1, 2, 3, and 4). Note that (c) represents the transfer signal (transfer 1) to be input to the gate of the transfer transistor 22A_1, (d) represents the transfer signal (transfer 2) to be input to the gate of the transfer transistor 22A_2, (e) represents the transfer signal (transfer 3) to be input to the gate of the transfer transistor 22B_1, and (f) represents the transfer signal (transfer 4) to be input to the gate of the transfer transistor 22B_2.

In this case, as shown in FIG. 25, at the first point-in-time t1, the transfer signals (transfer 3 and transfer 4) are also set to high level, unlike the case shown in FIG. 24. That is to say, the four transfer transistors 22A_1, 22A_2, 22B_1, and 22B_2 go on.

Also, as shown in FIG. 25, at the thirteenth point-in-time t13, the transfer signals (transfer 3 and transfer 4) are also set to high level, unlike the case shown in FIG. 24. That is to say, the four transfer transistors 22A_1, 22A_2, 22B_1, and 22B_2 go on. After a predetermined amount of time elapses, at the fourteenth point-in-time t14, transfer signals (transfer 1, transfer 2, transfer 3, and transfer 4) are set to low level, so that the four transfer transistors 22A_1, 22A_2, 22B_1, and 22B_2 go off.

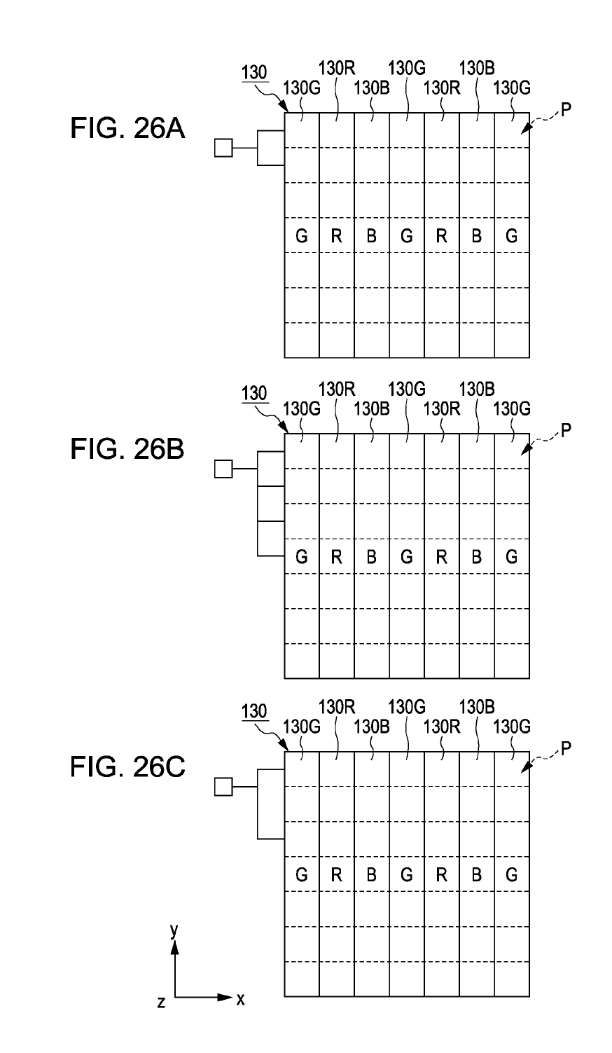

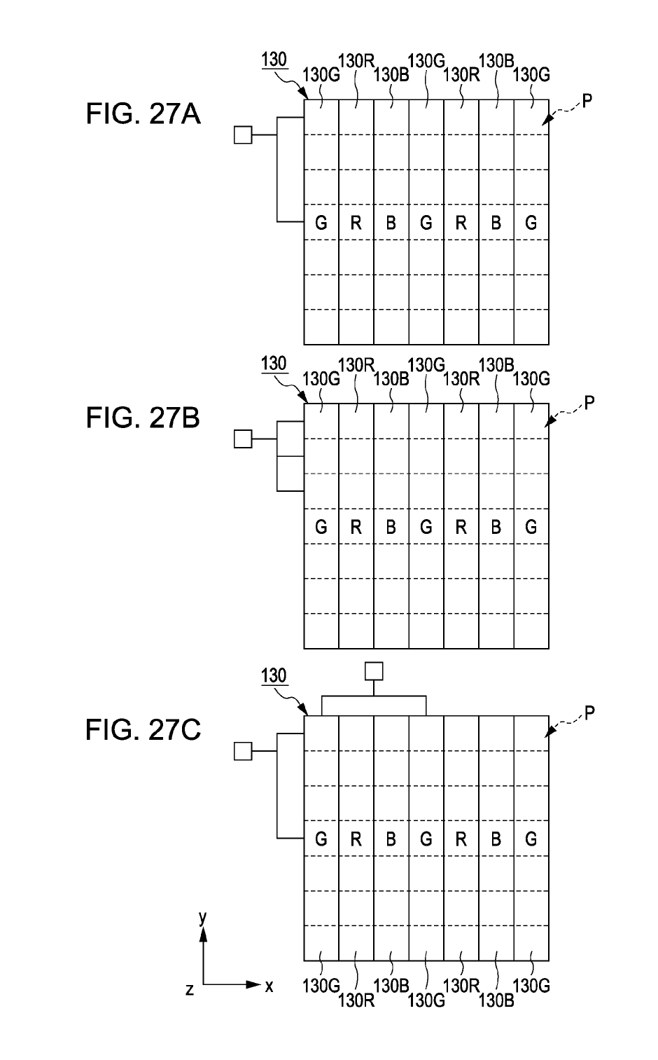

Other than these points, driving operations shown in FIG. 25 are performed in the same way as in FIG. 24. Other driving operations may be implemented as well. FIGS. 26A through 27C are diagrams schematically illustrating the operations of the solid-state imaging device in modifications of the seventh embodiment.

An arrangement may be made as shown in FIGS. 26A and 26B, wherein FD addition is performed among two or four consecutive pixels P in the vertical direction y, or, an arrangement may be made as shown in FIG. 26C, wherein FD addition is performed among non-consecutive pixels P. Specifically, an arrangement may be made as shown in FIG. 26C wherein every other pixel P in the vertical direction y is selected, and FD addition is performed.

Alternatively, as shown in FIG. 27A, an arrangement may be made wherein every two pixels P in the vertical direction y is selected, and FD addition is performed. Also, as shown in FIG. 27B, an arrangement may be made wherein FD addition is performed among three consecutive pixels P in the vertical direction y. Further, as shown in FIG. 27C, an arrangement may be made wherein column addition is performed among pixels P of the same color arrayed in the horizontal direction x.

### B. Conclusion

As described above, with the present embodiment, the filter layers 130R, 130G, and 130B, making up the color filter 130, extend in the vertical direction y above the photoreception face JS of the photodiodes 21 arrayed in the vertical direction y (see FIG. 7). Multiple transfer transistors 22 are arranged to read out signal charges from multiple photodiodes 21 arrayed in the vertical direction y to a single floating diffusion FD. The pixels P are driven such that the signal charge generated at the multiple photodiodes 21 arrayed in the vertical direction y are added at the floating diffusion FD.

Thus, pixels sharing in the vertical direction are of the same color array in the vertical direction, so FD addition can be performed easily. Specifically, all of the pixels P electrically connected to a single vertical signal line 27 are of the same color, so pixels P can be freely selected in various combinations in the vertical direction y. Thus, in addition to the advantages of the first embodiment, the present embodiment can realize reduction of noise by performing FD addition, thereby further improving image quality of the imaged image.

### 8. Eighth Embodiment

### A. Configuration of Apparatus, etc.

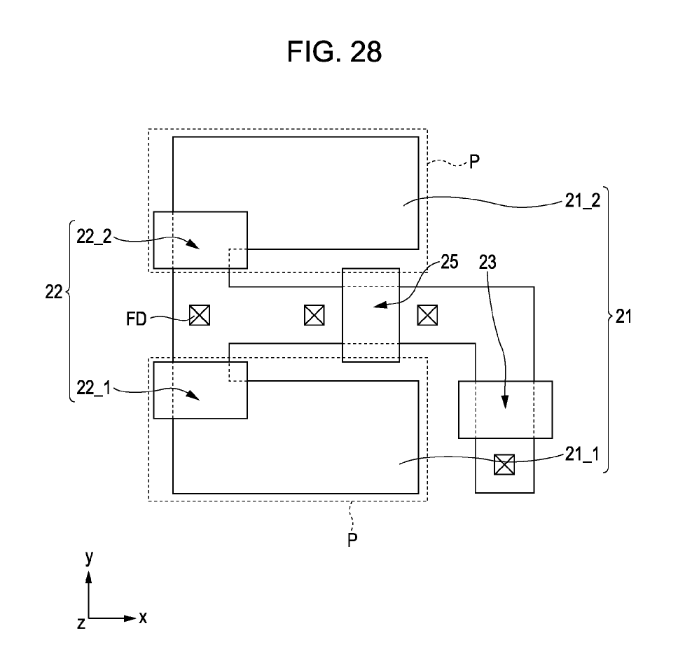

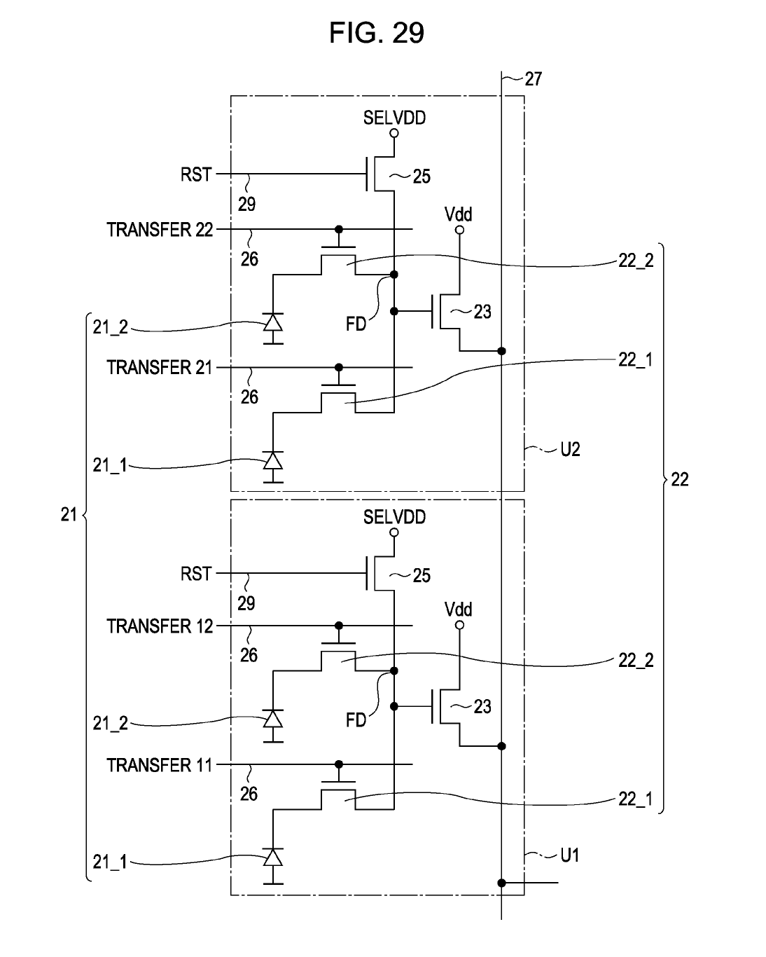

FIGS. 28 and 29 illustrate principal portions of a solid-state imaging device according to an eighth embodiment of the present invention. FIG. 28 schematically illustrates the upper face of pixels P, the same as with FIG. 22, and FIG. 29 illustrates the circuit configuration. As shown in FIGS. 28 and 29, the placement of members making up pixels P, and the circuit configuration thereof, differ from the seventh embodiment. Other than these and related points, the present embodiment is the same as with the seventh embodiment, so description of redundant portions will be omitted.

As shown in FIGS. 28 and 29, the solid-state imaging device according to the present embodiment includes photodiodes 21 and pixel transistors 50, the same as with the seventh embodiment. The members will be described in order.

### A-1. About the Photodiodes 21

Multiple photodiodes 21 are provided as shown in FIG. 28, corresponding to each of the multiple pixels P, as with the case of the seventh embodiment. As shown in FIGS. 28 and 29, with the present embodiment, transfer transistors 22 are provided to the photodiodes 21. More specifically, as shown in FIGS. 28 and 29, two transfer transistors 22 (22_1 and 22_2) are provided corresponding to two photodiodes 21 (21_1 and 21_2), in a one-to-one manner.

Further, as shown in FIGS. 28 and 29, the pair of photodiodes 21_1 and 21_2 arrayed in the vertical direction y are provided as to a single floating diffusion FD. Also, as shown in FIGS. 28 and 29, one amplifier transistor 23 and one reset transistor 25 are provided to the set of photodiodes 21_1 and 21_2 arrayed in the vertical direction y.

Specifically, as shown in FIG. 28, the floating diffusion FD is provided at the left portion between the photodiodes 21_1 and 21_2. The transfer transistors 22_1 and 22_2 are provided between the photodiodes 21_1 and 21_2 and the floating diffusion FD, respectively. The reset transistor 25 is provided to the right side portion between the photodiodes 21_1 and 21_2. The amplifier transistor 23 is provided to the right of the photodiodes 21_1 and 21_2.

### A-2. About the Pixel Transistor 50

As shown in FIGS. 28 and 29, the pixel transistor 50 includes transfer transistors 22, the amplifier transistor 23, and the reset transistor 25, as with the case of the seventh embodiment. With the present embodiment, a selection power source SELVDD is provided instead of the selecting transistor.

With the pixel transistor 50, multiple transfer transistors 22 are provided so as to correspond to the multiple pixels P, as shown in FIGS. 28 and 29. Here, as shown in FIG. 28, two transfer transistors 22_1 and 22_2 arrayed in the vertical direction y sandwich the floating diffusion FD provided between the two photodiodes 21_1 and 21_2. As shown in FIG. 29, the two transfer transistors 22_1 and 22_2 are configured to transfer signal charges from the photodiode 21_1 and 21_2, respectively, to the floating diffusion FD. That is to say, the gate of each of the transfer transistors 22_1 and 22_2 is electrically connected to a transfer line 26, and each of the transfer transistors 22_1 and 22_2 input transfer signals to transfer the signal charge to the floating diffusion FD.

With the pixel transistor 50, one amplifier transistor 23 and one reset transistor 25 are provided to a set of photodiodes 21_1 and 21_2, as shown in FIGS. 28 and 29. Further, as shown in FIG. 29, multiple sets configured of photodiodes 21 and a pixel transistor 50 are provided, as described above. For example, as shown in FIG. 29, a second set U2 of photodiodes 21 and a pixel transistor 50 is placed so as to be adjacent above a first set U1 of photodiodes 21 and a pixel transistor 50, as described above.

### A-3. Operations

Operations of the solid-state imaging device will be described.

With the present embodiment, signals from signal charges generated at multiple photodiodes 21 are added at a vertical signal line 27 (see FIG. 3) and output. That is to say, what is called “source follower (SF) addition” is performed.

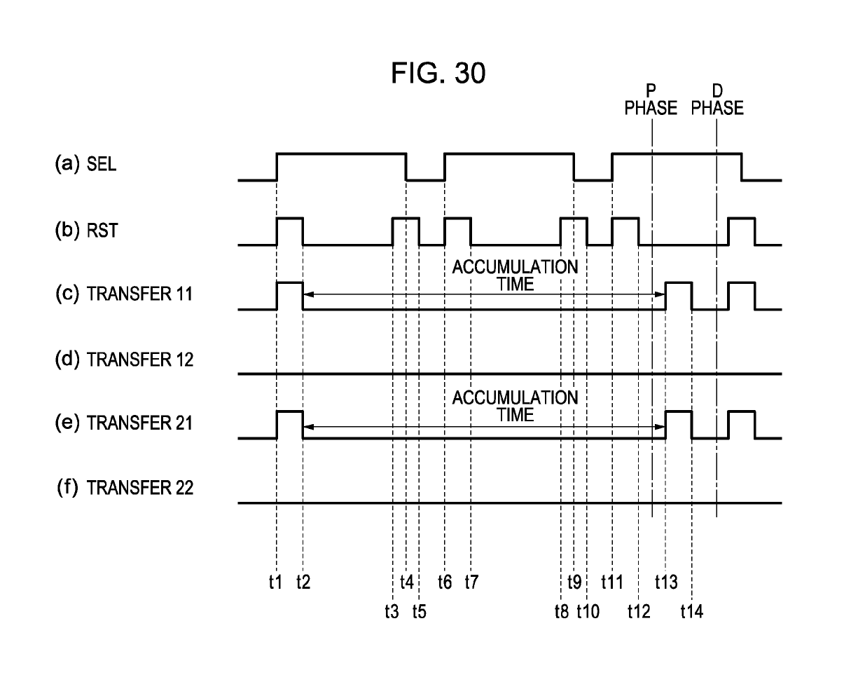

FIG. 30 is a timing chart illustrating operations of the solid-state imaging device according to the eighth embodiment. In FIG. 30, the same as with FIG. 24, (a) represents the potential of selection power source (SEL), (b) represents the reset signal (RST), and (c) through (f) represents transfer signals (transfer 11, 12, 21, and 22). Note that (c) represents the transfer signal (transfer 11) to be input to the gate of the transfer transistor 22A_1 included in the first set U1 shown in FIG. 29, and in the same way (d) represents the transfer signal (transfer 12) to be input to the gate of the transfer transistor 22_2 included in the first set U1. Also, (e) represents the transfer signal (transfer 21) to be input to the gate of the transfer transistor 22_1 included in the second set U2 shown in FIG. 29, and (f) represents the transfer signal (transfer 22) to be input to the gate of the transfer transistor 22_2 included in the second set U2.

First, as shown in FIG. 30, at a first point-in-time t1, the potential (SEL) of the selection power source SELVDD goes from low level to high level. Also, the reset signal (RST) is set to high level, so that the reset transistor 25 goes on. Along with this, the transfer signals (transfer 11 and transfer 21) are set to high level, so that one of the transfer transistors 22_1 included in the first set U1 and second set U2 go on. Thus, an “electronic shutter operation” where the charges of the photodiodes 21_1 are discharged and emptied is performed.

At a second point-in-time t2, the reset signal (RST) and transfer signals (transfer 11 and transfer 21) are set to low level as shown in FIG. 30, so that the reset transistor 25 and the two transfer transistors 22_1 go off.

As shown in FIG. 30, the accumulation period is then entered, and operations from the third point-in-time t3 through the twelfth point-in-time t12 are performed in the same way as with the case of the seventh embodiment. As shown in FIG. 30, a signal is output at the potential at the time of resetting, in P phase (preset phase). That is to say, voltage corresponding to the reset level is read out to the column circuit 14 (see FIG. 2).

Next, as shown in FIG. 30, at a thirteenth point-in-time t13, the transfer signals (transfer 11 and transfer 21) are set to high level, so that the one of the transfer transistors 22_1 included in the first set U1 and second set U2 go on. After a predetermined amount of time elapses, at a fourteenth point-in-time t14, transfer signals (transfer 11 and transfer 21) are set to low level, so that the transfer transistors 22_1 go off.

Thus, the signal charges accumulated in the photodiodes 21_1 in the sets U1 and U2 are transferred to the floating diffusion FD. As shown in FIG. 30, a signal is output at the potential of the floating diffusion FD, in D phase (data phase). That is to say, voltage of a signal level corresponding to the signal charges accumulated in the photodiodes 21_1 of the sets U1 and U2 are output to the vertical signal line 27 at the same time, and accordingly added at the vertical signal line 27 and output to the column circuit 14.

Subsequently, in the same way as with the first embodiment, the column circuit 14 performs difference processing regarding the reset level read out first, and the signal level read out later. Accordingly, fixed pattern noise generated due to irregularities in the threshold voltage Vth of the transistors provided at each pixel P is cancelled out from the pixel signals. Signals accumulated at the column circuit 14 are selected by the horizontal driving circuit 15, and sequentially output to the external output circuit 17 (see FIG. 2). Thus, driving of the solid-state imaging device is performed by SF addition.

Note that while a case of performing SD addition between two photodiodes 21_1 and 21_2 has been described, but the present embodiment is not restricted to this arrangement. For example, SF addition may be performed with various combinations, as described with the case of the seventh embodiment.

### B. Conclusion

As described above, with the present embodiment, the filter layers 130R, 130G, and 130B, making up the color filter 130, extend in the vertical direction y above the photoreception face JS of the photodiodes 21 arrayed in the vertical direction y (see FIG. 7). The pixels P are driven such that the signal charges generated at the multiple photodiodes 21 arrayed in the vertical direction y are added at the vertical signal line 27.

With the present embodiment, pixels sharing in the vertical direction are of the same color array in the vertical direction, so SF addition for thinning operations and high-speed imaging can be easily performed. Also, all of the pixels P electrically connected to a single vertical signal line 27 are of the same color, so pixels P can be freely selected in various combinations in the vertical direction y. Thus, the above advantages can be had in addition to the advantages of the first embodiment.

### 9. Others

It should be note that carrying out of the present invention is not restricted to the above-described embodiments, and that various modifications may be employed.

While description has been made above regarding a case of a backside illumination type solid-state imaging device, the present invention is not restricted to this arrangement, and the present invention may be applied to a case of a solid-state imaging device which receives incident light from the front side of the substrate where pixel transistors are provided.

Also, while description has been made above regarding a case of applying the present invention to a camera, the present invention is not restricted to this arrangement, and the present invention may be applied to other electronic devices having solid-state imaging devices, such as scanners or photocopiers.

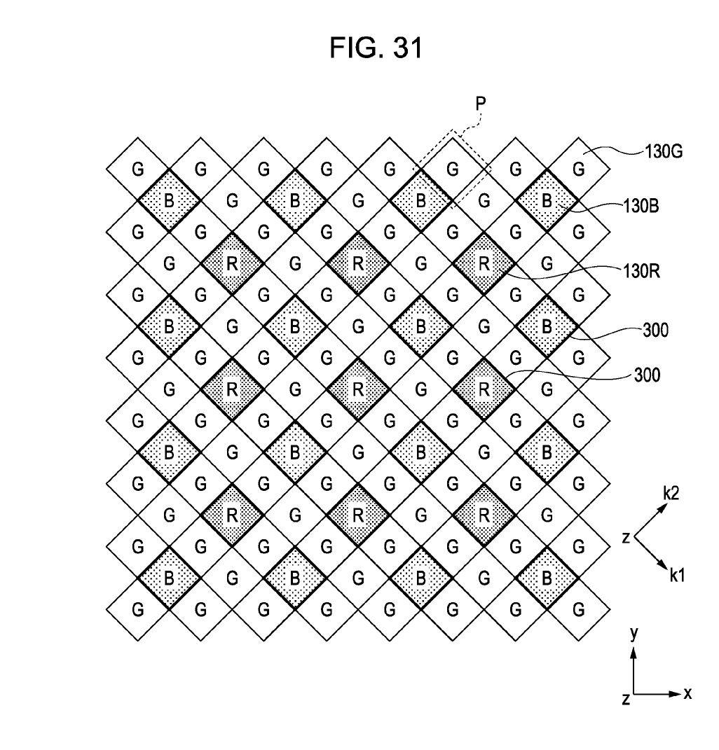

Also, while description has been made above regarding a case of filter layers of the three primary colors of red, blue, and green, being arrayed in stripe forms, the present invention is not restricted to this arrangement. FIG. 31 is a diagram illustrating a pixel array as a modification of an embodiment of the present invention. The array shown in FIG. 31 is called a clear bit pixel array, and the present invention may be applied to this case as well.

Specifically, as shown in FIG. 31, multiple pixels P are arrayed along first and second inclination directions k1 and k2, inclined as to the horizontal direction x and vertical direction y respectively, by an angle of 45°. The red filter layer 130R and the blue filter layer 130B are disposed so as to be adjacent one to another across one green filter layer 130G in both the first and second inclination directions k1 and k2. Moreover, the red filter layer 130R and the blue filter layer 130B are disposed so as to be adjacent one to another across one green filter layer 130G in both the horizontal direction x and vertical direction y.

Thus, as shown in FIG. 31, the green filter layer 130G is formed including portions extending in the first and second inclination directions k1 and k2 on the imaging face (x-y face), and is formed so as to surround the red filter layer 130R and blue filter layer 130B on the imaging face (x-y face).

The light shielding portions 300 are formed at the boundary portions between the green filter layer 130G and red filter layer 130R, and at the boundary portions between the green filter layer 130G and blue filter layer 130B, so as to surround the red filter layer 130R on the imaging face (x-y face) and also surround the blue filter layer 130B on the imaging face (x-y face). Thus, the light shielding portion 300 is formed between color filters of different colors, so occurrence of color mixing can be prevented as with the above embodiments, and image quality of the imaged image can be improved.

Further, besides a case of color filters of the three primary colors for pixel array, the present invention may be applied to cases of forming color filters for an array wherein yellow, magenta, and cyan form one set. That is to say, the present invention may be applied to a case of a complementary color filter.

Also, while description has been made above regarding a case of sharing a pixel transistor among two or four photodiodes, the present invention is not restricted to this arrangement, and the present invention is applicable to a case of sharing a pixel transistor among more than four photodiodes. That is to say, the present invention is applicable to any pixel array.

Note that in the above embodiments, the solid-state imaging devices 1, 1e, and 1f correspond to the solid-state imaging device in the Summary of the Invention.

Also, in the above embodiments, the photodiode 21 corresponds to the photoelectric conversion unit in the summary of the invention.

Also, in the above embodiments, the transfer transistor 22 corresponds to the transfer transistor in the Summary of the Invention.

Also, in the above embodiments, the camera 40 corresponds to the electronic device in the Summary of the Invention.

Also, in the above embodiments, the substrate 101 corresponds to the semiconductor substrate in the Summary of the Invention.

Also, in the above embodiments, the color filters 130, 130b, 130d, and 130f, correspond to the color filter in the summary of the invention.

Also, in the above embodiments, the blue filters 130B, 130Bb, 130Bd, and 130Bf, correspond to the first filter layer or second filter later in the Summary of the Invention.

Also, in the above embodiments, the green filters 130G, 130Gb, 130Gd, and 130Gf, correspond to the first filter layer or second filter later in the Summary of the Invention.

Also, in the above embodiments, the red filters 130R, 130Rb, 130Rd, and 130Rf, correspond to the first filter layer or second filter later in the Summary of the Invention.

Also, in the above embodiments, the light shielding portions 300, 300b, 300c, and 3000e, correspond to the light shielding portion in the Summary of the Invention.

Also, in the above embodiments, the floating diffusions FD, FDA, and FDB, correspond to the light shielding portion in the Summary of the Invention.

Also, in the above embodiments, the photoreception face JS corresponds to the photoreception face in the Summary of the Invention.

Also, in the above embodiments, the imaging region PA corresponds to the imaging face in the Summary of the Invention.

Also, in the above embodiments, the subject plane PS corresponds to the imaging face in the Summary of the Invention.

Also, in the above embodiments, the pixel transistor 50 corresponds to the semiconductor device in the Summary of the Invention.

Also, in the above embodiments, the horizontal direction x corresponds to the first direction or second direction in the Summary of the Invention.

Also, in the above embodiments, the vertical direction y corresponds to the first direction or second direction in the Summary of the Invention.

The present application contains subject matter related to that disclosed in Japanese Priority Patent Application JP 2009-205188 filed in the Japan Patent Office on Sep. 4, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device comprising:
photoelectric conversion units provided on an imaging face of a semiconductor substrate, said photoelectric conversion units being configured to generate signal charge by receiving incident light at a photoreception face;
a color filter provided on said imaging face, said color filter being configured to input said incident light and transmit said incident light to said photoreception face; and
a light shielding portion provided on said imaging face, said light shielding portion being configured to shield part of said incident light transmitted through said color filter;
wherein a plurality of said photoelectric conversion units are arrayed on said imaging face in a first direction and a plurality of said photoelectric conversion units are arrayed on said imaging face in a second direction orthogonal to said first direction;
and wherein said color filter includes at least
a first filter layer having high light transmissivity with regard to a first wavelength band, and
a second filter layer having high light transmissivity with regard to a second wavelength band which is different from said first wavelength band,
said first filter layer and said second filter layer each being arrayed above the photoreception faces of said plurality of photoelectric conversion units arrayed in said first direction so as to extend in said first direction and be arrayed adjacently in said second direction;
and wherein said light shielding portion is formed so as to extend in said first direction at boundary portions between said plurality of photoelectric conversion units arrayed in said second direction, at boundary portions between said first filter layer and said second filter layer.

2. The solid-state imaging device according to claim 1, wherein said light shielding portion is formed to further include portions extending in said second direction at boundary portions between said plurality of photoelectric conversion units arrayed in said first direction.

3. The solid-state imaging device according to claim 2, wherein said light shielding portion is formed such that the width of portions extending in said first direction is wider than the width of portions extending in said second direction.

4. The solid-state imaging device according to claim 1, wherein said first filter layer and said second filter layer are provided so as to include portions where one is layered upon another at boundary portions between said plurality of photoelectric conversion units arrayed in said second direction.

5. The solid-state imaging device according to claim 1, wherein said light shielding portion is formed such that the width of portions extending in said first direction increases the farther the position of placement thereof on said imaging face is away from the center of said imaging face.

6. The solid-state imaging device according to claim 4, wherein said first filter layer and said second filter layer are provided such that the area of portions where one is layered upon another increases the farther the position of placement thereof on said imaging face is away from the center of said imaging face.

7. The solid-state imaging device according to claim 1, further comprising:
a semiconductor device configured to
read out signal charges generated at said photoelectric conversion units and
output said signal charges as pixel signals to a signal line;
wherein said semiconductor device is provided to a face of said substrate opposite to said photoreception face.

8. The solid-state imaging device according to claim 1, said semiconductor device including
a plurality of transfer transistors configured to read out signal charges from said plurality of photoelectric conversion units to floating diffusion;
wherein said plurality of transfer transistors are formed so as to read out said signal charges from said plurality of photoelectric conversion units arrayed in said first direction, to one floating diffusion.

9. The solid-state imaging device according to claim 7, driven such that signal charges generated at from said plurality of photoelectric conversion units arrayed in said first direction are added at said one floating diffusion.

10. The solid-state imaging device according to claim 7, driven such that pixel signals from signal charges generated at from said plurality of photoelectric conversion units arrayed in said first direction are added at said signal line.

11. A solid-state imaging device comprising:
photoelectric conversion units provided on an imaging face of a semiconductor substrate, said photoelectric conversion units being configured to generate signal charge by receiving incident light at a photoreception face;
a color filter provided on said imaging face, said color filter being configured to input said incident light and transmit said incident light to said photoreception face; and
a light shielding portion provided on said imaging face, said light shielding portion being configured to shield part of said incident light transmitted through said color filter;
wherein a plurality of said photoelectric conversion units are arrayed on said imaging face in a first direction and a plurality of said photoelectric conversion units are arrayed on said imaging face in a second direction orthogonal to said first direction;
and wherein said color filter includes at least
a first filter layer having high light transmissivity with regard to a first wavelength band, and
a second filter layer having high light transmissivity with regard to a second wavelength band which is different from said first wavelength band,
said first filter layer being arrayed above the photoreception faces of said plurality of photoelectric conversion units arrayed in said first direction so as to extend in said first direction, and including portions where said first filter layer and said second filter layer are arrayed adjacently in said second direction;
and wherein said light shielding portion is formed between said plurality of photoelectric conversion units arrayed in said second direction, at boundary portions between said first filter layer and said second filter layer.

12. The solid-state imaging device according to claim 11, wherein said first filter layer is formed so as to surround the perimeter of said second filter layer in said first direction and said second direction;
and wherein said light shielding portion is formed between said plurality of photoelectric conversion units arrayed in said first direction and said second direction, at boundary portions between said first filter layer and said second filter layer.

13. An electronic device comprising:
photoelectric conversion units provided on an imaging face of a semiconductor substrate, said photoelectric conversion units being configured to generate signal charge by receiving incident light at a photoreception face;
a color filter provided on said imaging face, said color filter being configured to input said incident light and transmit said incident light to said photoreception face; and
a light shielding portion provided on said imaging face, said light shielding portion being configured to shield part of said incident light transmitted through said color filter;
wherein a plurality of said photoelectric conversion units are arrayed on said imaging face in a first direction and a plurality of said photoelectric conversion units are arrayed on said imaging face in a second direction orthogonal to said first direction;
and wherein said color filter includes at least
a first filter layer having high light transmissivity with regard to a first wavelength band, and
a second filter layer having high light transmissivity with regard to a second wavelength band which is different from said first wavelength band,
said first filter layer and said second filter layer each being arrayed above the photoreception faces of said plurality of photoelectric conversion units arrayed in said first direction so as to extend in said first direction and be arrayed adjacently in said second direction;
and wherein said light shielding portion is formed so as to extend in said first direction at boundary portions between said plurality of photoelectric conversion units arrayed in said second direction, at boundary portions between said first filter layer and said second filter layer.

14. A method for manufacturing a solid-state imaging device, said method comprising the steps of:
first formation, of photoelectric conversion units upon an imaging face of a semiconductor substrate, said photoelectric conversion units being configured to generate signal charge by receiving incident light at a photoreception face;
second formation, of a color filter upon said imaging face, said color filter being configured to input said incident light and transmit said incident light to said photoreception face; and
third formation, of a light shielding portion upon said imaging face, said light shielding portion being configured to shield part of said incident light transmitted through said color filter;
wherein, in said first formation, a plurality of said photoelectric conversion units are arrayed on said imaging face in a first direction and a plurality of said photoelectric conversion units are arrayed on said imaging face in a second direction orthogonal to said first direction;
and wherein said second formation further includes at least the steps of
fourth formation, of a filter layer having high light transmissivity with regard to a first wavelength band, and
fifth formation, of a second filter layer having high light transmissivity with regard to a second wavelength band which is different from said first wavelength band,
said first filter layer and said second filter layer each being formed, in said fourth formation and fifth formation, so as to be arrayed above the photoreception faces of said plurality of photoelectric conversion units arrayed in said first direction so as to extend in said first direction and be arrayed adjacently in said second direction;
and wherein, in said third formation, said light shielding portion is formed so as to extend in said first direction at boundary portions between said plurality of photoelectric conversion units arrayed in said second direction, at boundary portions between said first filter layer and said second filter layer.
